(19) United States
(12) Patent Application Publication
(10) Pub. No.: US 2026/0047157 A1
(43) Pub. Date: Feb. 12, 2026

(54) NANOSHEET DEVICES WITH GATE ISOLATION STRUCTURES AND METHODS OF FABRICATING THE SAME

(71) Applicant: Taiwan Semiconductor Manufacturing Company, Ltd., Hsinchu (TW)

(72) Inventors: Po-Hsun Chu, Hsinchu (TW); Ze-Xian LU, Hsinchu (TW); Chia-En Huang, Hsinchu (TW); Pin-Dai Sue, Hsinchu (TW); Jung-Hsuan CHEN, Hsinchu (TW); Ting-Wei Chiang, Hsinchu (TW)

(73) Assignee: Taiwan Semiconductor Manufacturing Company, Ltd., Hsinchu (TW)

(21) Appl. No.: 19/009,734

(22) Filed: Jan. 3, 2025

Related U.S. Application Data
(60) Provisional application No. 63/681,281, filed on Aug. 9, 2024.

(51) Int. Cl. H10D 62/13; H10D 30/00; H10D 62/10; H10D 84/01; H10D 84/83

(52) U.S. Cl. CPC H10D 62/151; H10D 30/501; H10D 62/116; H10D 84/013; H10D 84/0153; H10D 84/832

(57) ABSTRACT

A semiconductor structure includes a semiconductor fin protruding from a substrate and extending across the substrate along a first lateral direction. The semiconductor structure includes a plurality of gate structures disposed over the substrate, where each gate structure extends along a second lateral direction perpendicular to the first lateral direction. The semiconductor structure includes a gate isolation structure disposed over the gate structures. The gate isolation structure including a first portion and a second portion connected to the first portion. The first portion extends over the gate structures along the first lateral direction. The second portion partially extends into the semiconductor fin along the second lateral direction.

### CROSS-REFERENCE TO RELATED PATENT APPLICATIONS

This application claims priority to U.S. Provisional Application Ser. No. 63/681,281, filed Aug. 9, 2024, the entire disclosure of which is incorporated herein for all purposes.

### BACKGROUND

As the semiconductor industry has progressed into nanometer technology process nodes in pursuit of higher device density, higher performance, and lower costs, challenges from both fabrication and design issues have resulted in the development of multi-gate devices, such as fin field-effect transistors (FinFETs) and gate-all-around (GAA) transistors. To continue to provide the desired scaling and increased density for multi-gate devices in advanced technology nodes, reducing a device area while maintaining device performance is desirable. While various schemes have been implemented to provide area-saving benefit in fabrication of integrated circuits (ICs), they have not been entirely satisfactory in every aspect.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 2A, 3A, 4A, 5A, 6A, and 7A each illustrate a top view layout of an example semiconductor device, in portion or in entirety, according to some embodiments of the present disclosure.

FIGS. 1B, 2B, 3B, 4B, 6B, and 7B each illustrate a cross-sectional view of the example semiconductor device, in portion or in entirety, taken along line AA′ of FIGS. 1A, 2A, 3A, 4A, 5A, 6A, and 7A, respectively, according to some embodiments of the present disclosure.

FIGS. 1C, 3D, 4C, 6D, and 7D each illustrate a cross-sectional view of the example semiconductor device, in portion or in entirety, taken along line BB′ of FIGS. 3A, 4A, 6A, and 7A, respectively, according to some embodiments of the present disclosure.

FIGS. 3E, 4D, 6E, and 7E each illustrate a cross-sectional view of the example semiconductor device, in portion or in entirety, taken along line CC′ of FIGS. 3A, 4A, 6A, and 7A, respectively, according to some embodiments of the present disclosure.

FIGS. 3C, 6C, and 7C each illustrate a cross-sectional view of the example semiconductor device, in portion or in entirety, taken along line DD′ of FIGS. 3A, 6A, and 7A, respectively, according to some embodiments of the present disclosure.

FIG. 5B illustrates a cross-sectional view of the example semiconductor device, in portion or in entirety, taken along line AA′ or line DD′ of FIG. 5A, according to some embodiments of the present disclosure.

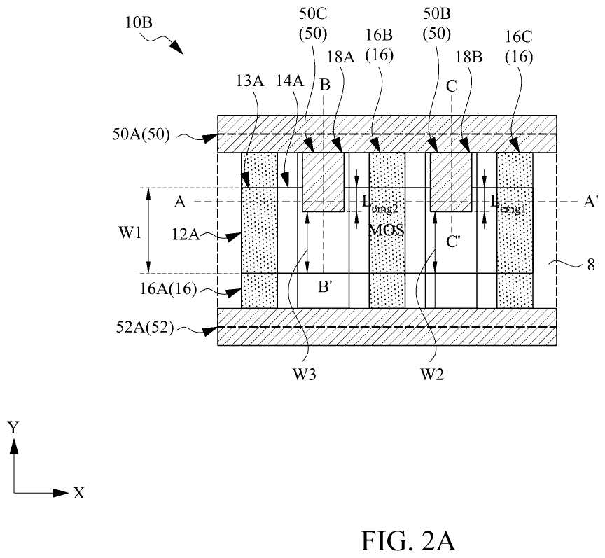

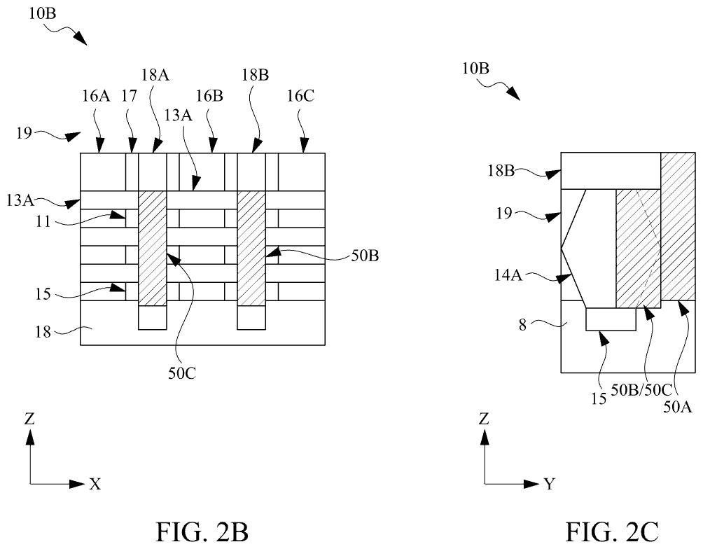

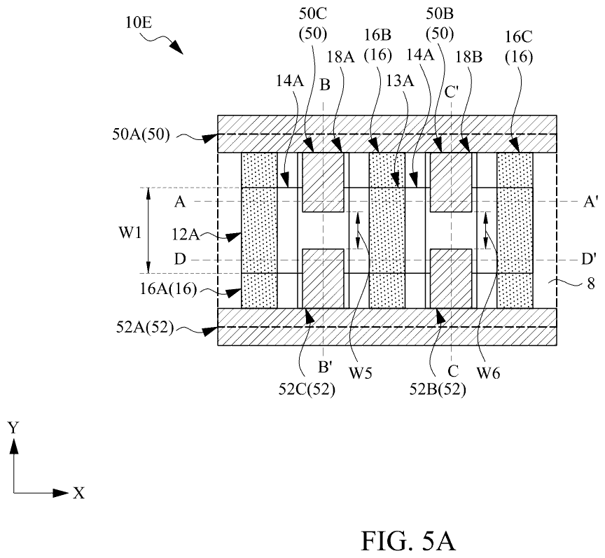

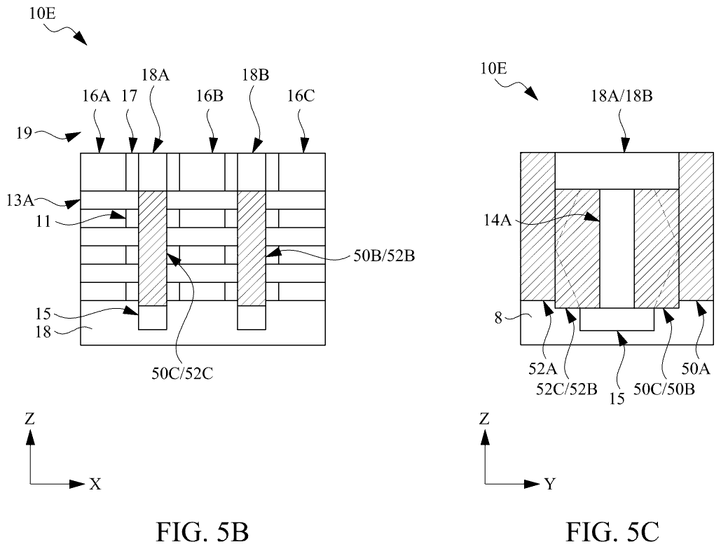

FIGS. 2C and 5C each illustrate a cross-sectional view of the example semiconductor device, in portion or in entirety, taken along line BB′ or line CC′ of FIGS. 2A and 5A, respectively, according to some embodiments of the present disclosure.

FIG. 8A illustrates an example schematic of a memory device, in portion or in entirety, according to some embodiments of the present disclosure.

FIGS. 8B and 8C each illustrate an example layout corresponding to a portion of the memory device of FIG. 8A, according to some embodiments of the present disclosure.

FIG. 9A illustrates an example circuit diagram of a portion of a memory device, according to some embodiments of the present disclosure.

FIGS. 9B, 9C, 9D, and 9E each illustrate an example layout corresponding to the portion of the memory device of FIG. 9A, according to some embodiments of the present disclosure.

FIG. 10A illustrates an example circuit diagram of a logic device, in portion or in entirety, according to some embodiments of the present disclosure.

FIGS. 10B and 10C each illustrate an example layout corresponding to the logic device of FIG. 10A, according to some embodiments of the present disclosure.

FIG. 11A illustrates an example circuit diagram of a logic device, in portion or in entirety, according to some embodiments of the present disclosure.

FIGS. 11B and 11C each illustrate an example layout corresponding to the logic device of FIG. 11A, according to some embodiments of the present disclosure.

FIG. 12 illustrates a three-dimensional perspective view of an example semiconductor device, in portion or in entirety, according to some embodiments of the present disclosure.

FIG. 13 illustrates a flow chart of an example method for fabricating an example semiconductor device, in portion or in entirety, according to some embodiments of the present disclosure.

FIGS. 14, 17, 18, and 19 each illustrate a cross-sectional view of an example semiconductor device, in portion or in entirety, taken along line XX′ of FIG. 12 and during intermediate steps of the method of FIG. 13, according to some embodiments of the present disclosure.

FIGS. 15 and 16 each illustrate a cross-sectional view of the example semiconductor device, in portion or in entirety, taken along line YY′ of FIG. 12 and during intermediate steps of the method of FIG. 13, according to some embodiments of the present disclosure.

FIG. 20 illustrates a top view of the example semiconductor device, in portion or in entirety, during an intermediate step of the method of FIG. 13, according to some embodiments of the present disclosure.

FIG. 21 illustrates a flowchart of a method of manufacturing a semiconductor device, in accordance with some embodiments.

FIG. 22 illustrates a block diagram of a system of generating an IC layout design, in accordance with some embodiments.

FIG. 23 illustrates a block diagram of an IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

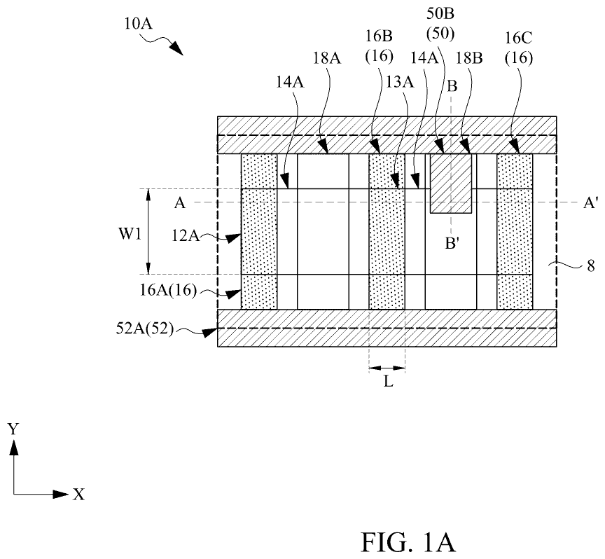

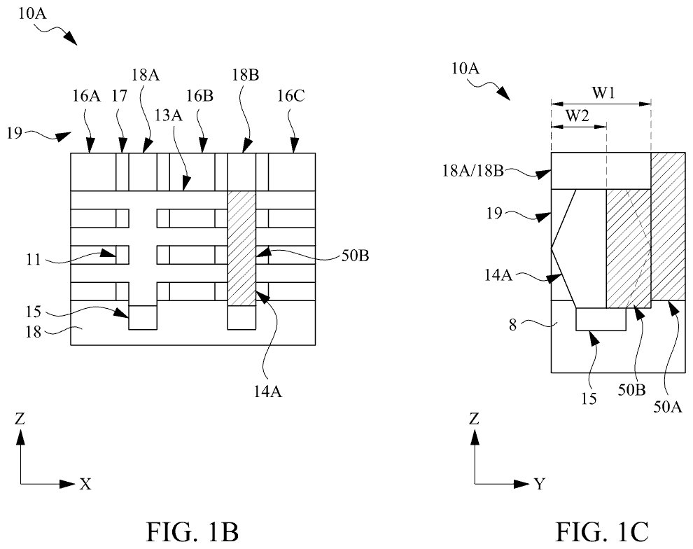

Referring to FIGS. 1A, 1B, and 1C, a semiconductor device 10A (hereafter referred to as device 10A) is provided over a semiconductor substrate 8 (hereafter referred to as substrate 8). FIG. 1A depicts a top view of the device 10A, FIG. 1B depicts a cross-sectional view of the device 10A taken along line AA′, and FIG. 1C depicts a cross-sectional view of the device 10A taken along line BB′.

The device 10A includes at least one active region 12A disposed on or over the substrate 8, where the active region 12A extends lengthwise along a first lateral direction (i.e., the X axis). As will be described in detail below, the device 10A includes one or more metal-oxide-semiconductor (MOS) devices (e.g., MOS field-effective transistor or MOSFETs) formed on or over the active region 12A. Although only one active region 12A is depicted in FIGS. 1A-1C, the device 10A may include any suitable number of the active regions extending parallel to the active region 12A. The depicted MOS device in FIGS. 1A-1C may be a PMOS transistor or an NMOS transistor. In some embodiments, the active region 12A is configured as a three-dimensional semiconductor structure protruding from the substrate 8 and may be referred to as a semiconductor fin 12A, a fin structure 12A, or the like.

In some embodiments, the substrate 8 includes a semiconductor material such as silicon (Si), silicon germanium (SiGe), a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GalnP, and/or GaInAsP, any other suitable materials, or combinations thereof. In some embodiments, the substrate 8 includes an epitaxial layer. For example, the substrate 8 may include an epitaxial layer overlying a bulk semiconductor. Furthermore, the substrate 8 may include a semiconductor-on-insulator (SOI) structure. For example, the substrate 8 may include a buried oxide (BOX) layer formed by a process such as separation by implanted oxygen (SIMOX) or other suitable technique, such as wafer bonding and grinding. The substrate 8 may include one or more doped wells, such as a p-type doped well (P-well) and an n-type doped well (N-well), where the P-well is configured to provide one or more n-channel or n-type MOS devices (i.e., NMOS transistors) and the N-well is configured to provide one or more p-channel or p-type MOS devices (i.e., PMOS transistors).

Referring to FIG. 1B, the active region 12A may be configured as a semiconductor fin structure that includes a plurality of nanostructures 13A stacked along a vertical direction (i.e., the Z axis). The nanostructures 13A include a semiconductor material and are configured as a plurality of channels of the MOS device that engage one or more active gate structures. In the present disclosure, the nanostructures 13A may be alternatively referred to as semiconductor layers 13A or channel layers 13A. Although the nanostructures 13A are depicted as nanosheets in the present embodiments, the nanostructures 13A may be alternatively formed as other types of structures, such as nanorods or nanowires, for example.

The nanostructures 13A may include any suitable semiconductor material, such as silicon (Si), silicon germanium (SiGe), a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GalnP, and/or GaInAsP, any other suitable materials, or combinations thereof. In some embodiments, the nanostructures 13A are substantially free of any dopant (e.g., p-type dopant o n-type dopant). In some embodiments, the nanostructures 13A are intentionally doped. For example, the nanostructures 13A may be doped with a p-type dopant such as boron (B), aluminum (Al), indium (In), gallium (Ga), other p-type dopants, or combinations thereof. Alternatively, the nanostructures 13A may be doped with an n-type dopant such as phosphorus (P), arsenic (As), antimony (Sb), other n-type dopants, or combinations thereof.

Though not depicted herein, the device 10A also includes isolation structures disposed over the substrate 8 and surrounding bottom portions of the active region 12A. The isolation structures are configured to electrically isolate neighboring active regions (e.g., the active region 12A) from one another. In some embodiments, the isolation structures include shallow-trench isolation (STI) structures.

Referring to FIGS. 1A-1C, the device 10C includes source/drain features 14A each electrically coupled to an end of the nanostructures 13A along the first lateral direction such that the source/drain features 14A and the nanostructures 13A together form the active region 12A. As such, the source/drain features 14A each extend vertically over the entire stack of the nanostructures 13A and share the same dimension as the nanostructures 13A along the second lateral direction. In other words, a width of the active region 12A defines a width of the nanostructures 13A and the source/drain features 14A along the second lateral direction. For embodiments in which the MOS device is configured as an NMOS transistor, the source/drain features 14A may include Si doped with an n-type dopant described herein. For embodiments in which the MOS device is configured as a PMOS transistor, the source/drain feature 14A may include SiGe doped with a p-type dopant described herein. Each of the source/drain features 14A may be configured as a source feature or a drain feature, according to various embodiments of the present disclosure.

In some embodiments, referring to FIGS. 1B and 1C, the device 10A includes a bottom isolation layer 15 embedded in the substrate 8. The bottom isolation layer 15 is disposed below the source/drain feature 14A such that a top surface of the bottom isolation layer 15 abuts a bottom surface of the source/drain feature 14A. The bottom isolation layer 15 is configured to reduce or prevent current leakage between adjacent source/drain features 14A. In some embodiments, the bottom isolation layer 15 includes any suitable dielectric material, such as silicon oxide, silicon nitride, silicon oxynitride, silicon carbonitride, silicon oxycarbonitride, silicon oxycarbide, other suitable dielectric materials, or combinations thereof.

Still referring to FIGS. 1A and 1B, the device 10A includes a plurality of active gate structures 16A, 16B, and 16C (collectively referred to active gate structures 16) each having at least a bottom (or lower) portion that wraps around each nanostructure 13A. In this regard, the bottom portion of the active gate structure 16 is interleaved with the stack of the nanostructures 13A. Furthermore, the active gate structure 16 includes a top (or upper) portion disposed over a topmost nanostructure 13A in the stack. Each active gate structure 16 extends along a second lateral direction (i.e., the Y axis) and generally perpendicular to the active region 12A. Although only three active gate structures 16 are depicted in FIGS. 1A-1C, the device 10A may include any suitable number of the active gate structures 16.

In some embodiments, the active gate structure 16 includes a gate dielectric layer and a gate metal over the gate dielectric layer (not depicted separately in FIGS. 1A and 1B). The gate dielectric layer may include any suitable dielectric material, such as a high-k dielectric material (e.g., a dielectric material having a dielectric constant greater than that of silicon oxide, which is about 3.9). Example high-k dielectric materials include a metal oxide or a metal silicate of Hf, Al, Zr, La, Mg, Ba, Ti, Pb, any other suitable materials, or combinations thereof. Additionally or alternatively, the gate dielectric layer may include silicon oxide, silicon oxynitride, other suitable dielectric materials, or combinations thereof. The gate dielectric layer may include a stack of multiple different dielectric materials.

The gate metal may include a stack of multiple metal materials. For example, the gate metal may include at least a work function layer (not depicted separately) and a conductive fill layer (not depicted separately) disposed over the work function layer. The work function layer may include a p-type work function layer, an n-type work function layer, multi-layers thereof, any other suitable materials, or combinations thereof. The work function layer may also be referred to as a work function metal. Example work function metals may include TiN, TaN, Ru, Mo, Al, WN, ZrSi₂, MoSi₂, TaSi₂, NiSi₂, Ti, Ag, TaAl, TaAIC, TiAIN, TaC, TaCN, TaSiN, Mn, Zr, other suitable materials, or combinations thereof. The conductive fill layer may include any suitable conductive material, such as polycrystalline silicon (polysilicon), tungsten (W), copper (Cu), cobalt (Co), ruthenium (Ru), aluminum (Al), titanium (Ti), tantalum (Ta), gold (Au), silver (Ag), platinum (Pt), other suitable conductive materials, or combinations (or alloys) thereof. The active gate structure 16 may further include additional layers, such as glue layers (or adhesive layers), capping layers, barrier layers, other suitable layers, or combinations thereof.

Referring to FIG. 1B, the device 10A includes inner spacers 11 interposed between a portion of the active gate structure 16 and the source/drain features 14A along the first lateral direction. The device 10A further includes gate spacers 17 each extending along a sidewall of the top portion of the active gate structure 16. The inner spacers 11 and the gate spacers 17 may each include any dielectric material, such as silicon oxide, silicon nitride, silicon oxycarbonitride, other suitable materials, combinations thereof. The inner spacers 11 and the gate spacers 17 may each include multiple layers of different dielectric materials. The inner spacers 11 and the gate spacers 17 may include the same or different dielectric material(s). It is noted that, for purposes of simplicity, the gate spacers 17 are omitted in the depiction in FIG. 1A.

Still referring to FIGS. 1A-1C, the device 10A further includes various source/drain contacts 18A, 18B, and 18C (collectively referred to as source/drain contacts 18) each electrically coupled to and overlaying a corresponding one of the source/drain features 14A. The source/drain contacts 18 each extend along the second lateral direction and spaced from one another along the first lateral direction. In this regard, the source/drain contacts 18 extend parallel to the active gate structures 16 and perpendicular to the active region 12A. In the depicted embodiments, the source/drain contacts 18 are each disposed between two adjacent active gate structures 16.

The source/drain contacts 18 may include a conductive fill layer (not depicted separately) having a conductive material such as W, Cu, Co, Ru, Al, Ti, Ta, Au, Ag, Pt, other suitable conductive materials, or combinations (or alloys) thereof. The source/drain contact 18 may include a barrier layer (not depicted) separating the conductive fill layer from the surrounding components. The barrier layer may include Ti, Ta, TiN, TaN, other suitable materials, or combinations thereof. The source/drain contact 18 may further include a metal silicide layer (not depicted) disposed between the conductive fill layer and the underlying source/drain features 14A. The metal silicide layer may include, for example, NiSi.

In some embodiments, referring to FIG. 1C, the device 10A further includes an interlayer dielectric (ILD) layer 19 that is disposed over the source/drain features 14A and surrounds or embeds a top portion of the MOS device. The ILD layer 19 may include any dielectric material, such as an oxide, a nitride, a low-k dielectric material (examples described above), other suitable dielectric materials, or combinations thereof.

In the present embodiments, the device 10A further includes a plurality of gate isolation structures 50 and 52 (alternatively referred to as gate cut features 50 and 52) at least partially extending across the active gate structures 16. In some embodiments, the gate isolation structures 50 and 52 are configured to separate active gate structures into segments, provide desired scaling, and increased density for devices such as the depicted MOS device at advanced technology nodes. In some embodiments, the gate isolation structures 50 and 52 each abut sidewalls of the active gate structures 16 that extend along the first lateral direction. The gate isolation structures 50 and 52 may each include any suitable dielectric material, such as silicon oxide, silicon nitride, other suitable materials, or combinations thereof. Although two gate isolation structures are depicted in FIGS. 1A-1C, the device 10A may include any suitable number of the gate isolation structures similar to the gate isolation structure 50 and/or the gate isolation structure 52.

Referring to FIG. 1A, for example, the gate isolation structure 50 includes a first portion 50A (alternatively referred to as a horizontal portion 50A) and a second portion 50B (alternatively referred to as a first transverse portion 50B) extending from and connected to the first portion 50A along the second lateral direction. The first portion 50A generally extends along the first lateral direction and parallel to the active region 12A. In the present embodiment, the first portion 50A is disposed between two adjacent active regions, one of which is depicted as the active region 12A. Referring to FIGS. 1A-1C, the second portion 50B generally extends along the second lateral direction from the first portion 50A towards the active region 12A, thereby intersecting one of the source/drain features 14A. As such, the second portion 50B is generally perpendicular to the first portion 50A. In the depicted embodiment, the second portion 50B is disposed between the active gate structures 16B and 16C. Furthermore, in some embodiments, the second portion 50B is equidistant to each of the act gate structures 16B and 16C along the first lateral direction.

As depicted in FIG. 1A, the second portion 50B partially penetrates or truncates the source/drain feature 14A such that an end portion of the second portion 50B is surrounded by portions of the source/drain feature 14A. In other words, referring to FIGS. 1B and 1C, the end portion of the second portion 50B replaces a portion of the source/drain feature 14A. Furthermore, as the second portion 50B extends along the second lateral direction, a portion of the source/drain contact 18B overlaps the second portion 50B (and a segment of the first portion 50A as depicted herein). Referring to FIG. 1C, a sidewall of the second portion 50B abuts and directly contacts a sidewall of the source/drain feature 14A along the vertical direction. In some embodiments, one of the source/drain contacts 18 extends over and directly contacts a top surface of the second portion 50B, as depicted in FIGS. 1A-1C. Furthermore, a bottom surface of the second portion 50B abuts a top surface of the bottom isolation layer 15. In this regard, at least in some embodiments, the second portion 50B selectively replaces a portion of the source/drain feature 14A without penetrating the bottom isolation layer 15.

Referring to FIG. 1A, the gate isolation structure 52 includes a first portion 52A (alternatively referred to as a horizontal portion 52A) that generally extends along the first lateral direction and parallel to the first portion 50A of the gate isolation structure 50. The first portion 50A of the gate isolation structure 50 and the first portion 52A of the gate isolation structure 52 are spaced apart along the second lateral direction with the active region 12A disposed therebetween. As depicted in the device 10A, the gate isolation structure 52 differs from the gate isolation structure 50 in that the gate isolation structure 52 does not include any transverse portion similar to the second portion 50B of the gate isolation structure 50. In other words, the gate isolation structure 52 is completely free of contact with the active region 12A as depicted in FIGS. 1A-1C.

In the present embodiments, the active region 12A has a width W1 extending along the second lateral direction. In this regard, the stack of nanostructures 13A engaging each active gate structure 16 has the width W1, and a first one of the source/drain features 14A disposed between the first portion 50A and the gate isolation structure 52 also has the width W1. Referring to FIGS. 1A and 1C, a portion of a second one of the source/drain features 14A disposed between the second portion 50B and the gate isolation structure 52 has a width W2 extending along the second lateral direction, where the width W2 is less than the width W1. In this regard, as the second portion 50B intersects the source/drain feature 14A, it reduces the width of the active region 12A such that the width W2 is a fraction of the width W1. In the present embodiments, the width W2 is greater than 0 and less the width W1, i.e., the second portion 50B does not fully truncate or replace the second one of the source/drain features 14A along the second lateral direction. Stated differently, a ratio of W2/W1 is greater than 0 and less than 1.

A current I_{d} (alternatively referred to as a drain current) of the MOS device described herein may be generally defined by the mathematical expression in Equation I

$${I}_{d} = μ \times \frac{W}{L} \times {C}_{o x} \times {( {V}_{G S} - {V}_{T} )}^{2} , \qquad ( I )$$

where μ represents carrier mobility applicable to the type of MOS device (e.g., n-channel or n-type MOS device, p-channel or p-type MOS device, etc.), W represents a width of the active region (e.g., a dimension along a widthwise direction of the active region), L is a length of the active region (e.g., a dimension along a lengthwise direction of the active region), Cₒₓ represents capacitance of the gate dielectric layer (e.g., gate oxide) of the active gate structure, V_{GS} represents the gate-source voltage of the MOS device, and V_{T} represents the threshold voltage of the MOS device. In this regard, the current I_{d} is generally proportional to the width of the active region and inversely proportionally to the length of the active region. In other words, the current I_{d} may be tuned by adjusting the size of the MOS device, among other factors. Still referring to Equation I, the device 10A may be represented by an equivalent circuit such that the current I_{d} may be defined by Equation II:

$${I}_{d} = \frac{{V}_{e}}{{R}_{e}} , \qquad ( II )$$

where Vₑ and Rₑ represent the voltage and the resistance of the equivalent circuit, respectively. For example, Rₑ can be defined as a sum of R_{ch}, resistance of channel (i.e., the stack of nanostructures 13A), R_{S}, resistance of the source (i.e., one of the source/drain features 14A), and R_{D}, resistance of the drain (i.e., the other one of the source/drain features 14A), as shown in Equation II′ below:

$${R}_{e} = {R}_{c h} + {R}_{S} + {R}_{D} , \qquad ( II ’ )$$

In various instances, it may be beneficial to reduce the current I_{d} produced by the MOS device, while all other factors remain constant according to Equation I, to achieve specific design goals. As channel widths in conventional nanosheet devices (e.g., GAA devices) are generally fixed and quantized, options for tuning the current I_{d}, which influences timing margin of the devices, are limited. For example, existing technologies have generally employed the approach of electrically coupling a multitude of MOS devices in series, thereby increasing the length L of the active region, to reduce the current I_{d} of the resulting equivalent device. For example, a plurality of serially coupled PMOS transistors may be used for generating a low leakage current in a keeper circuit (in a peripheral circuit) of a memory device. While such an approach is generally adequate, it has not been entirely satisfactory in all aspects. For example, increasing the number of serially coupled MOS devices may be implemented at the cost of an increased device footprint (i.e., area), rendering it difficult to scale the devices at advanced technology nodes.

In the present disclosure, embodiments provide structures of MOS devices that allow the current I_{d} to be adjusted by utilizing a two-dimensional gate isolation structure (as depicted in a top view, for example) that partially cuts or truncates the active region of the MOS device along the second lateral direction (i.e., the widthwise direction of the active region). In this regard, the width W of the active region is reduced and the current I_{d}, which is related to the width W by Equation I, can also be reduced. In existing technologies, the gate isolation structures generally extend parallel to and are disposed between two adjacent active regions. As such, each gate isolation structure is configured to isolate (e.g., electrically and/or physically) one or more active gate structures into two separate regions or segments disposed along the second lateral direction. In some instances, the gate isolation structures are alternatively referred to as gate-cut features that physically truncate otherwise continuous active gate structures into isolated segments.

In the present embodiments, however, at least one of the gate isolation structures (e.g., the gate isolation structure 50 in FIGS. 1A-1C) includes a horizontal portion (e.g., the first portion 50A) and a transverse portion (e.g., the second portion 50B) extending from the horizontal portion. In this regard, the horizontal portion extends along the first lateral direction, i.e., parallel to the active region (e.g., the active region 12A), and the transverse portion extends along the second lateral direction, i.e., parallel to the active gate structure (e.g., the active gate structures 16). The transverse portion replaces a portion, not an entirety, of a source/drain feature (e.g., the source/drain feature 14A) disposed in the active region, effectively reducing the width W of the active region of the given MOS device. In various embodiments, the two-dimensional gate isolation structures provided herein may improve design flexibility of MOS devices without incurring additional area cost of the device footprint, which may be beneficial especially at advanced technology nodes. In addition, such approach of modifying existing structural features (e.g., the gate isolation structures) reduces or removes the requirement for additional photomasks and/or additional fabrication steps to obtain active regions of different dimensions, thereby reducing the overall complexity and cost of device fabrication process.

In the present embodiments, referring to FIGS. 1A-1C, the second portion 50B reduces the width W1 of the active region 12A to the width W2, resulting in I_{d_adj}, an adjusted current that is less than the current I_{d}. In some embodiments, the replacement of a portion of the active region 12A (e.g., the first one of the source/drain features 14A) by the second portion 50B, which includes an electrically insulating material, effectively increases the resistance of one of the source/drain features 14A (i.e., R_{S} or R_{D} as defined in Equation II′ above) to R_{s_cmg1} or R_{D_cmg1}, and thus increases the resistance portion Rₑ of the equivalent series circuit. Accordingly, the adjusted current I_{d_adj} may be defined as

$${I}_{d \_ adj} = \frac{{V}_{e}}{{R}_{e}^{′}} = \frac{{V}_{e}}{{R}_{c h} + {R}_{S \_ cmg 1} + {R}_{D}} < {I}_{d} or \qquad ( III )$$

$${I}_{d \_ adj} = \frac{{V}_{e}}{{R}_{e}^{′}} = \frac{{V}_{e}}{{R}_{c h} + {R}_{S} + {R}_{D \_ cmg 1}} < {I}_{d} , \qquad ( III ’ )$$

which is less than the current I_{d} as defined in Equations I and II above. In this regard, the extent of such reduction in the current I_{d} is generally related to the resistance R_{D_mg1} (or R_{S_cmg1}), which may be positively correlated with (e.g., vary proportionally to) a length L_{cmg1} of the second portion 50B, the length L_{cmg1} being the length of a portion of the second portion 50B that replaces the first one of the source/drain features 14A. Mathematically, the length L_{cmg1} is a difference between the width W1 and the width W2. As a result, a decrease in the width W2 corresponds to an increase in the length L_{cmg1}, which causes an increase in the resistance R_{D_cmg1}, leading to further reduction in the adjusted current I_{d_adj}. Stated differently, a reduction in the width W2 leads to a reduction in the adjusted current I_{d_adj}.

In some embodiments, the reduction in the adjusted current I_{d_adj} can be achieved by utilizing more than one transverse portion of the gate isolation structures similar to the gate isolation structure 50 to effectively introduces or contributes additional resistance to the source/drain feature(s) 14A, and thus the resistance portion Rₑ, of the equivalent series circuit, thereby increasing the resistance portion Rₑ and decreasing the adjusted current I_{d_adj}. For example, referring to FIGS. 2A, 2B, and 2C, a semiconductor device 10B (hereafter referred to as device 10B) is provided. FIG. 2A depicts a top view of the device 10B, FIG. 2B depicts a cross-sectional view of the device 10B taken along line AA′, and FIG. 2C depicts a cross-sectional view of the device 10B taken along line BB′ or line CC′.

The device 10B is substantially similar to the device 10A with the exception that the gate isolation structure 50 in the device 10B further includes a third portion 50C (alternatively referred to as a second transverse portion 50C) that extends from the first portion 50A towards the second one of the source/drain features 14A along the second lateral direction. In this regard, as shown in FIG. 2A, the second portion 50B and the third portion 50C are substantially parallel to one another. Referring to FIGS. 2A-2C, the third portion 50C truncates or replaces a portion of the second one of the source/drain features 14A, thereby reducing the width W1 of the active region 12A to a width W3, where the width W3 is less than the width W1.

Accordingly, similar to the effect of the second portion 50B on the adjusted current I_{d_adj}, a ratio of W3/W1 is greater than 0 and less than 1. Furthermore, in combination with the second portion 50B, which reduces the width W1 of the active region 12A (in the first one of the source/drain features 14A) to the width W2, the adjusted current I_{d_adj} of the MOS device depicted in FIGS. 2A-2C can be determined based on the resistance contribution of the second portion 50B (cmg1) to the source feature 14A (or the drain feature 14A) and a resistance contribution of the third portion 50C (cmg2) to the drain feature 14A (or the source feature 14A), according to Equation IV:

$${I}_{d \_ adj} = \frac{{V}_{e}}{{R}_{c h} + {R}_{S \_ cmg 2} + {R}_{D \_ cmg 1}} < {I}_{d} . \qquad ( IV )$$

In some embodiments, the adjusted current I_{d_adj} may be tuned by independently varying the widths W2 and W3. Stated differently, the adjusted current I_{d_adj} may be tuned by configuring the shape and dimension of the gate isolation structure 50. For example, each of the resistance R_{S_cmg} and R_{D_cmg} may be independently tuned by varying the length L_{cmg1} (i.e., varying the width W2) of the second portion 50B and a length L_{cmg2} (i.e., varying the width W3) of the third portion 50C, respectively. Advantageously, without utilizing the gate isolation structures described herein, to achieve an adjusted current I_{d_adj} that is a fraction of the current I_{d} would require multiple MOS devices to be electrically coupled in series along the active region 12A, thereby increasing an area occupied by the device 10B as defined by a number of center-poly pitches (CPPs) of the active gate structures 16, for example.

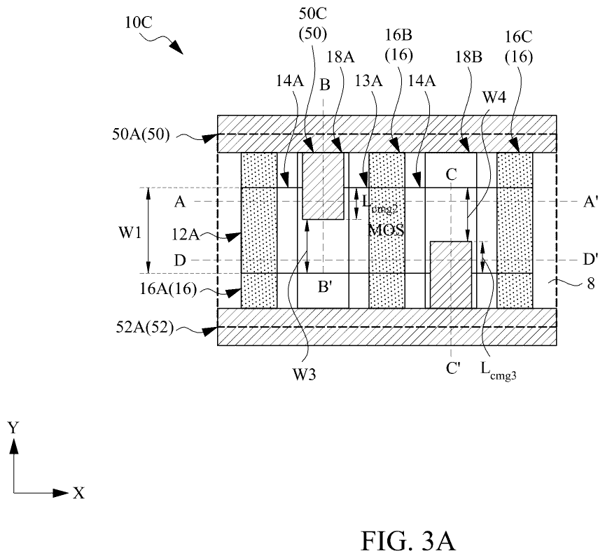

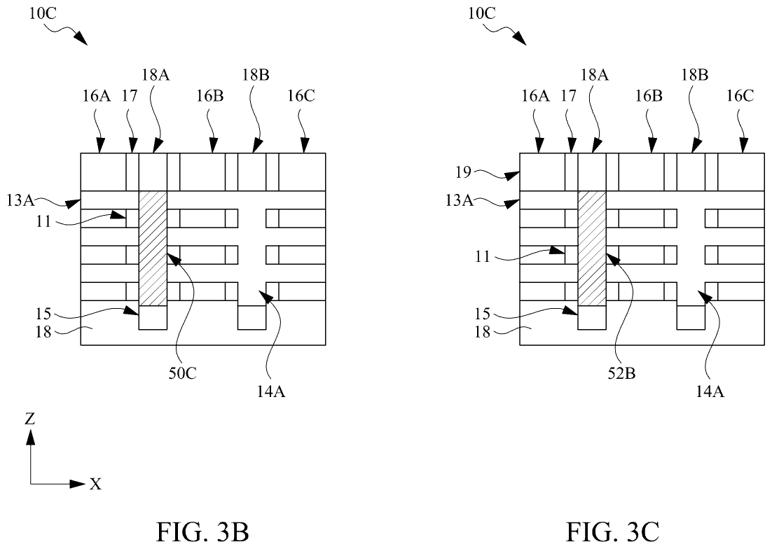

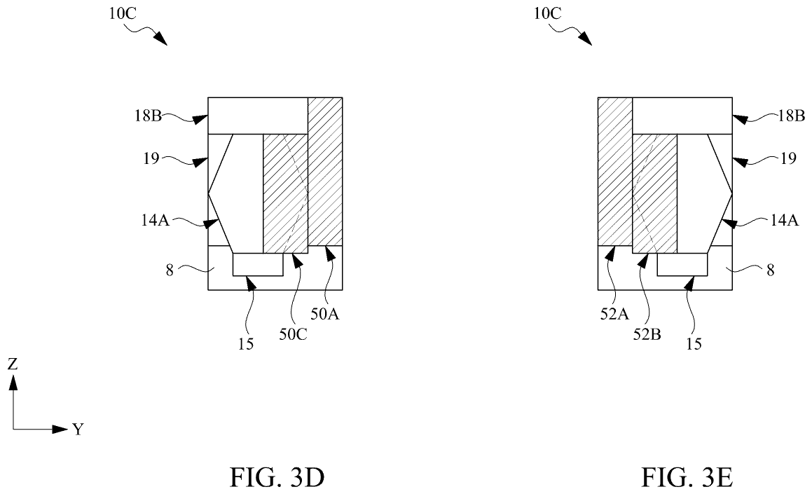

Referring to FIGS. 3A, 3B, 3C, 3D, and 3E, a semiconductor device 10C (hereafter referred to as device 10C) is provided. FIG. 3A depicts a top view of the device 10C, FIG. 3B depicts a cross-sectional view of the device 10C taken along line AA′, FIG. 3C depicts a cross-sectional view of the device 10C taken along line DD′, FIG. 3D depicts a cross-sectional view of the device 10C taken along line BB′, and FIG. 3E depicts a cross-sectional view of the device 10C taken along line CC′.

The device 10C is substantially similar to the device 10B with the exception that the gate isolation structure 52 in the device 10C includes a second portion 52B (alternatively referred to as a first transverse portion 52B) that extends from the first portion 52A towards the first one of the source/drain features 14A along the second lateral direction, and that the gate isolation structure 50 does not include the second portion 50B as the case in the device 10B. As shown in FIG. 3A, the third portion 50C and the second portion 52B are substantially parallel to one another and facing one another. Referring to FIGS. 3A-3E, the second portion 52B truncates or replaces a portion of the first one of the source/drain features 14A, thereby reducing the width W1 of the active region 12A to a width W4.

Accordingly, similar to the effect of the second portion 50B on the adjusted current I_{d_adj}, a ratio of W4/W1 is greater than 0 and less than 1. Furthermore, in combination with the third portion 50C, which reduces the width W1 of the active region 12A (in the second one of the source/drain features 14A) to the width W3, the adjusted current I_{d_adj} of the MOS device depicted in FIGS. 3A-3E can be determined based on the resistance contribution of the third portion 50C (cmg2) to the source feature 14A and a resistance contribution of the second portion 52B (cmg3) to the drain feature 14A, according to Equation V:

$${I}_{d \_ adj} = \frac{{V}_{e}}{{R}_{c h} + {R}_{S \_ cmg 2} + {R}_{D \_ cmg 3}} < {I}_{d} , \qquad ( V )$$

where the resistance R_{S_cmg2} increases with an increased length L_{cmg2} and a decreased width W3 and the resistance R_{D_cmg3} increases with an increased length L_{cmg3} and a decreased width W4.

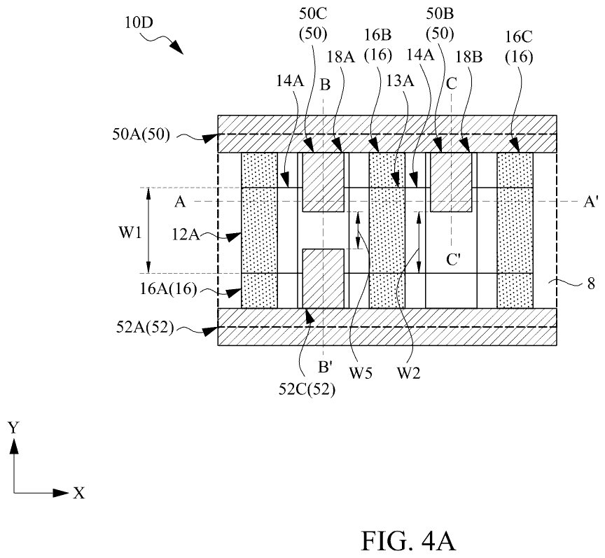

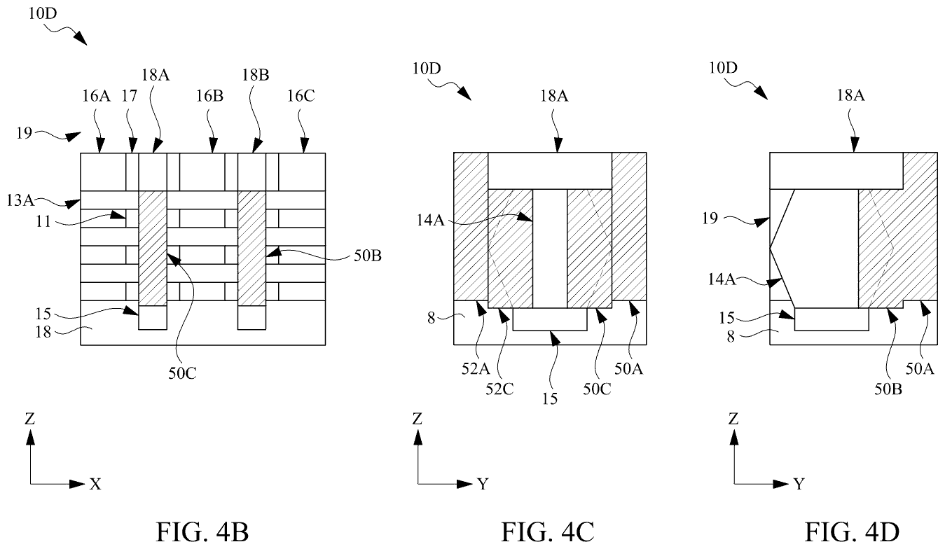

Referring to FIGS. 4A, 4B, 4C, and 4D, a semiconductor device 10D (hereafter referred to as device 10D) is provided. FIG. 4A depicts a top view of the device 10D, FIG. 4B depicts a cross-sectional view of the device 10D taken along line AA′, FIG. 4C depicts a cross-sectional view of the device 10D taken along line BB′, and FIG. 4D depicts a cross-sectional view of the device 10D taken along line CC′.

The device 10D is substantially similar to the device 10B with the exception that the gate isolation structure 52 in the device 10D includes a third portion 52C (alternatively referred to as a second transverse portion 52C) that extends from the first portion 52A towards the second one of the source/drain features 14A along the second lateral direction. In this regard, as shown in FIG. 4A, the third portion 52C of the gate isolation structure 52 and the second portion 50B of the gate isolation structure 50 are substantially parallel to one another and the third portion 52C extends in a direction facing the third portion 50C of the gate isolation structure 50. Furthermore, the gate isolation structure 52 does not include the second portion 52B such as that depicted in FIGS. 3A-3E.

Referring to FIGS. 4A-4D, each of the third portion 50C and the third portion 52C truncates or replaces a portion of the second one of the source/drain features 14A, thereby reducing the width W1 of the active region 12A to a width W5. In the depicted embodiment, the third portion 50C and the third portion 52C replace opposite end portions of the second one of the source/drain features 14A along the second lateral direction.

Accordingly, similar to the effect of the second portion 50B on the adjusted current I_{d_adj}, a ratio of W5/W1 is greater than 0 and less than 1. Furthermore, in combination with the second portion 50B, which reduces the width W1 of the active region 12A (in the first one of the source/drain features 14A) to the width W2, the adjusted current I_{d_adj} of the MOS device depicted in FIGS. 4A-4D can be determined based on the resistance contribution of the second portion 50B (cmg1) to the drain feature 14A, the resistance contribution of the third portion 50C (cmg2) to the source feature 14A, and a resistance contribution of the third portion 52C (cmg4) to the source feature 14A, according to Equation VI:

$${I}_{d \_ adj} = \frac{{V}_{e}}{{R}_{c h} + {R}_{S \_ cmg 2 + c m g 4} + {R}_{D \_ cmg 1}} < {I}_{d} , \qquad ( VI )$$

where the resistance R_{D_mg1} increases with a decreased width W2 and the resistance R_{S_cmg2+cmg4} increases with a decreased width W5.

Similar to the embodiment depicted in FIGS. 2A-2C, the adjusted current I_{d_adj} in the device 10D may be tuned by independently varying the widths W2 and W5 to achieve a desired reduction in the current I_{d} without requiring additional MOS devices to be incorporated. In some examples, the embodiment depicted in FIGS. 4A-4D allows for additional flexibility in the design and fabrication of the device 10D as the width W5 may be varied by configuring the dimension of one or both of the third portion 50C and the third portion 52C.

Referring to FIGS. 5A, 5B, and 5C, a semiconductor device 10E (hereafter referred to as device 10E) is provided. FIG. 5A depicts a top view of the device 10E, FIG. 5B depicts a cross-sectional view of the device 10E taken along line AA′ or line DD′, and FIG. 5C depicts a cross-sectional view of the device 10E taken along line BB′ or line CC′.

The device 10E is substantially similar to the device 10D with the exception that the gate isolation structure 52 in the device 10D additionally includes the second portion 52B that extends from the first portion 52A towards the first one of the source/drain features 14A along the second lateral direction. In this regard, as shown in FIG. 5A, the second portion 52B and the third portion 52C of the gate isolation structure 52 are substantially parallel to one another and the second portion 52B of the gate isolation structure 52 extends in a direction facing the second portion 50B of the gate isolation structure 50.

Referring to FIGS. 5A-5C, each of the second portion 50B of the gate isolation structure 50 and the second portion 52B of the gate isolation structure 52 truncates or replaces a portion of the first one of the source/drain features 14A, thereby reducing the width W1 of the active region 12A to a width W6, where the width W6 is less than the width W1. In the depicted embodiment, the second portion 50B and the second portion 52B replace opposing end portions of the first one of the source/drain features 14A along the second lateral direction.

Accordingly, similar to the effect of the second portion 50B on the adjusted current I_{d_adj}, a ratio of W6/W1 is greater than 0 and less than 1. Furthermore, in combination with the third portion 50C of the gate isolation structure 50 and the third portion 52C, which each truncate or replace a portion of the second one of the source/drain features 14A, the adjusted current I_{d_adj} in the MOS device depicted in FIGS. 5A-5C can be determined based on the resistance contribution of the second portion 50B (cmg1) to the drain feature 14A, the resistance contribution of the third portion 50C (cmg2) to the source feature 14A, the resistance contribution of the second portion 52B (cmg3) to the drain feature 14A, and the resistance contribution of the third portion 52C (cmg4) to the source feature 14A, according to Equation VII:

$${I}_{d \_ adj} = \frac{{V}_{e}}{{R}_{c h} + {R}_{S \_ cmg 2 + c m g 4} + {R}_{{D}_{c m g 1 + c m g 3}}} < {I}_{d} , \qquad ( VII )$$

where the resistance R_{D_cmg1+cmg3} increases with a decreased width W6 and the resistance R_{S_cmg2+cmg4} increases with a decreased width W5.

In some examples, if the width W5 is substantially similar to or the same as the width W3 and the width W6 is substantially similar to or the same as the width W2, then the MOS device depicted in FIGS. 5A-5C and the MOS device depicted in FIGS. 2A-2C are configured to generate the same adjusted current I_{d_adj} according to the expression of Equation I, assuming that other factors of Equation I are held constant. Further, if the width W6 is substantially similar to or the same as the width W2, then the MOS device depicted in FIGS. 5A-5C and the MOS device depicted in FIGS. 4A-4D are configured to generate the same adjusted current I_{d_adj} according to the expression of Equation I, assuming that other factors of Equation I are held constant. Still further, if the width W5 is substantially similar to or the same as the width W3 and the width W6 is substantially similar to or the same as the width W4, then the MOS device depicted in FIGS. 5A-5C and the MOS device depicted in FIGS. 3A-3E are configured to generate the same adjusted current I_{d_adj} according to the expression of Equation I, assuming that other factors of Equation I are held constant. Accordingly, gate isolation structures of various configurations and dimensions as provided herein may be employed to achieve the same adjusted current I_{d_adj}, thereby enabling more flexible current tuning options for devices at advanced technology nodes.

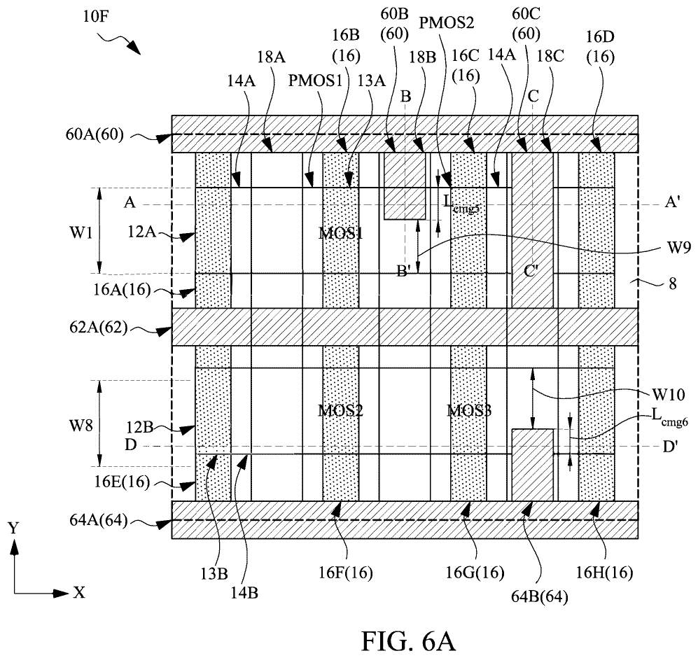

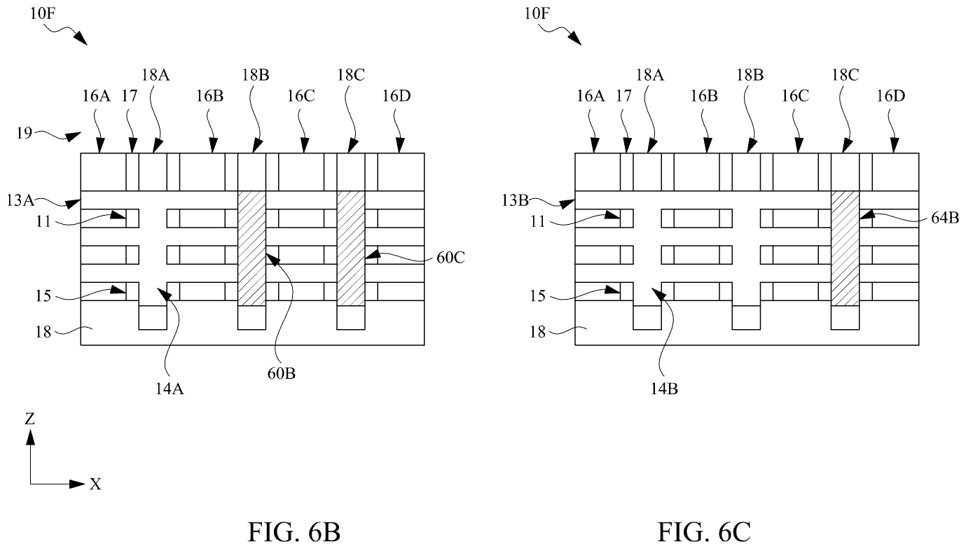

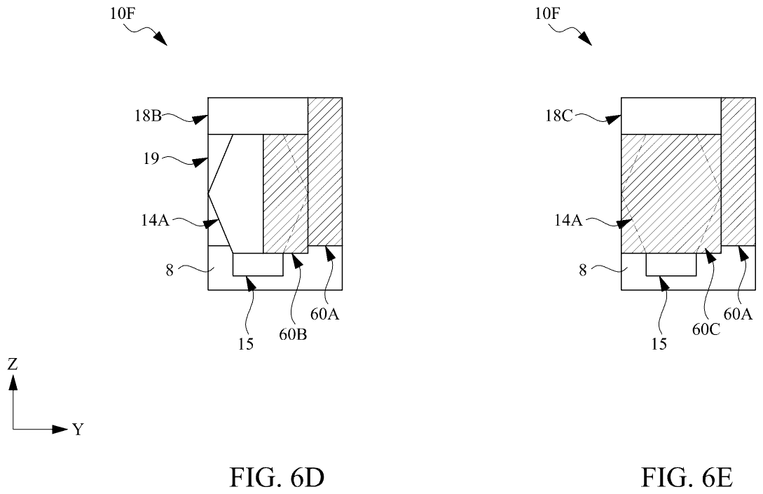

Referring to FIGS. 6A, 6B, 6C, 6D, and 6E, a semiconductor device 10F (hereafter referred to as device 10F) is provided. FIG. 6A depicts a top view of the device 10F, FIG. 6B depicts a cross-sectional view of the device 10F taken along line AA′, FIG. 6C depicts a cross-sectional view of the device 10F taken along line DD′, FIG. 6D depicts a cross-sectional view of the device 10F taken along line BB′, and FIG. 6E depicts a cross-sectional view of the device 10F taken along line CC′.

The device 10F, while having components similar to those of the device 10A, includes an additional active region 12B extending parallel to the active region 12A and an additional active gate structure 16D extending parallel to the active gate structures 16A-16C. The active region 12B includes a stack of nanostructures 13B and source/drain features 14B similar to the nanostructures 13A and the source/drain features 14A, respectively (though they may include dopants of different conductivity types). The active region 12A may be defined by the width W1 and the active region 12B may be defined by the width W8 that is the same as or different from the width W1. For embodiments in which the active regions 12A and 12B are configured to provide MOS devices of different conductivity types, the width W1 may differ from the width W8. In the present embodiments, various gate isolation structures described herein provide design options to further tune the width of each of the active regions, similar to that described above with respect to devices 10A-10E of FIGS. 1A-5C.

The device 10F further includes a plurality of active gate structures 16E, 16F, 16G, and 16H extending along the second lateral direction from the active gate structures 16A, 16B, 16C, and 16D (collectively referred to as active gate structures 16), respectively. Each pair of the active gate structures 16 arranged along the second lateral direction are separated by a gate isolation structure 62, which extends over a first end of each of the active gate structures 16A-16D opposite to a second end of each of the active gate structures 16A-16D. Similarly, the gate isolation structure 62 is disposed across a first end of each of the active gate structures 16E-16H opposite to a second end of each of the active gate structures 16E-16H. The device 10F further includes a gate isolation structure 60 extending over the second end of each of the active gate structures 16A-16D and a gate isolation structure 64 extending over the second end of each of the active gate structures 16E-16H. Accordingly, horizontal portions of the gate isolation structures 60, 62, and 64 extend parallel to one another along the first lateral direction and are configured to isolate adjacent active gate structures 16 along the second lateral direction, similar to the structure and function of the gate isolation structures 50 and 52 described herein.

In the depicted embodiment, referring to FIGS. 6A-6E, the gate isolation structure 60 includes a first portion 60A (alternatively referred to as a horizontal portion 60A), a second portion 60B (alternatively referred to as a first transverse portion 60B), and a third portion 60C (alternatively referred to as a second transverse portion 60C), each of the second portion 60B and the third portion 60C extending from the first portion 60A along the second lateral direction. The first portion 60A extends along the first lateral direction and perpendicular to the second portion 60B and the third portion 60C. The second portion 60B and the third portion 60C are spaced apart from one another along the first lateral direction. Specifically, the second portion 60B is disposed between the active gate structures 16B and 16C and the third portion 60C is disposed between the active gate structure 16C and 16D. The gate isolation structure 64 includes a first portion 64A (alternatively referred to as a horizontal portion 64A) and a second portion 64B (alternatively referred to as a transverse portion 64B) extending from the first portion 64A along the second lateral direction. The gate isolation structure 62 includes a first portion 62A (alternatively referred to as a horizontal portion 62A) that extends along the first lateral direction. In the depicted embodiment, referring to FIGS. 6A and 6E, the third portion 60C extends through the active region 12A (i.e., replaces an entire portion of one of the source/drain features 14A) and couples the first portion 60A of the gate isolation structure 60 with the gate isolation structure 62 along the second lateral direction.

In some embodiments, the active region 12A and the active region 12B engage the active gate structures 16A-16D and 16E-16H, respectively, to provide MOS devices of different conductivity types. For example, the active region 12A (i.e., the stack of nanostructures 13A) engages the active gate structure 16B to form a first MOS device MOS1, the pair of source/drain features 14A disposed on or straddling sidewalls of the active gate structure 16B. The active region 12B (i.e., the stack of nanostructures 13B), on the other hand, engages the active gate structure 16F to form a second MOS device MOS2 and engages the active gate structure 16G to form a third MOS device MOS3, a pair of the source/drain features 14B disposed on each side of the active gate structure 16F and the active gate structure 16G, respectively. In some embodiments, the source/drain features 14A include one or more p-type dopants described herein, rendering the MOS1 a PMOS transistor and, and the source/drain features 14B include one or more n-type dopants described herein, rendering the MOS2 and MOS3 NMOS transistors.

Similar to the effect of the second portion 50B and/or the third portion 50C of the gate isolation structure 50, the second portion 60B of the gate isolation structure 60 and the second portion 64B of the gate isolation structure 64 are configured to reduce the width of the active regions 12A and 12B, respectively. For example, referring to FIGS. 6A, 6B, and 6D, the second portion 60B truncates or replaces a portion of a first one of the source/drain features 14A, thereby reducing the width W1 of the active region 12A to a width W9, where a ratio of W9/W1 is greater than 0 and less than 1. Similarly, referring to FIGS. 6A and 6C, the second portion 64B truncates or replaces a portion of a first one of the source/drain features 14B, thereby reducing a width W8 of the active region 12B to a width W10, where a ratio of W10/W8 is greater than 0 and less than 1. Furthermore, referring to FIGS. 6A and 6E, the third portion 60C completely replaces a second one of the source/drain features 14A, thereby bridging or coupling the gate isolation structure 60 with the gate isolation structure 62 and effectively isolating the MOS1 from an adjacent device (not depicted herein).

Accordingly, an adjusted current I_{d_adj} of the MOS1 can be determined based on a resistance contribution of the second portion 60B (cmg5) to the drain feature 114A (or the source feature 14A) of the MOS1, according to Equation VIII:

$${I}_{d \_ adj} = \frac{{V}_{e}}{{R}_{c h} + {R}_{S} + {R}_{D \_ cmg 5}} < {I}_{d} , \qquad ( VIII )$$

where the resistance R_{D_cmg5} increases with an increased length L_{cmg5} and a decreased width W9. Similarly, an adjusted current I_{d_adj} of the MOS3 can be determined based on a resistance contribution of the second portion 64B (cmg6) to the source feature 14A (or the drain feature 14A) of the MOS3, according to Equation IX:

$${I}_{d \_ adj} = \frac{{V}_{e}}{{R}_{c h} + {R}_{S \_ cmg 6} + {R}_{D}} < {I}_{d} , \qquad ( IX )$$

where the resistance R_{S_cmg6} increases with an increased length L_{cmg6} and a decreased width W10.

For embodiments in which the MOS1 is configured as a PMOS transistor and the MOS2 and MOS3 are configured as NMOS transistors, the adjusted current I_{d_adj} in the MOS devices of different conductivity types may be tuned independently by changing the dimensions (e.g., the width W9 and/or W10) of one or more of the transverse portions of the gate isolation structures 60, 62, and/64 according to Equations I, VIII, and IX described herein.

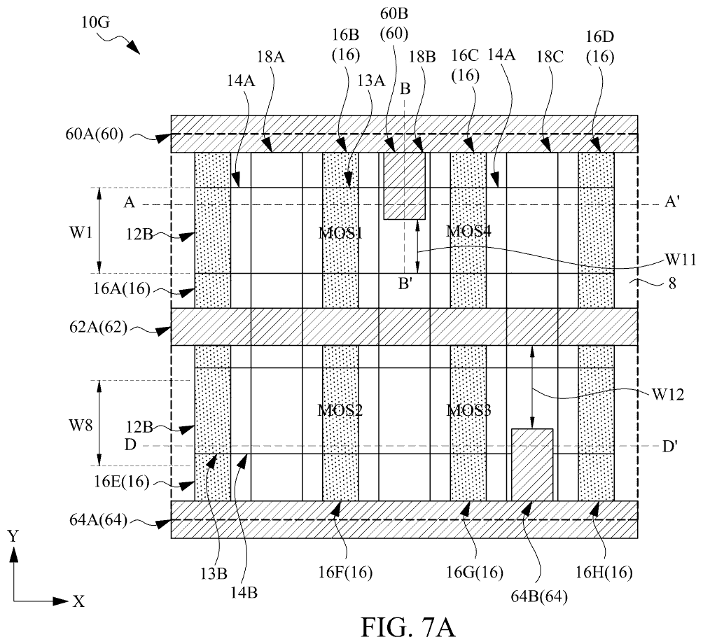

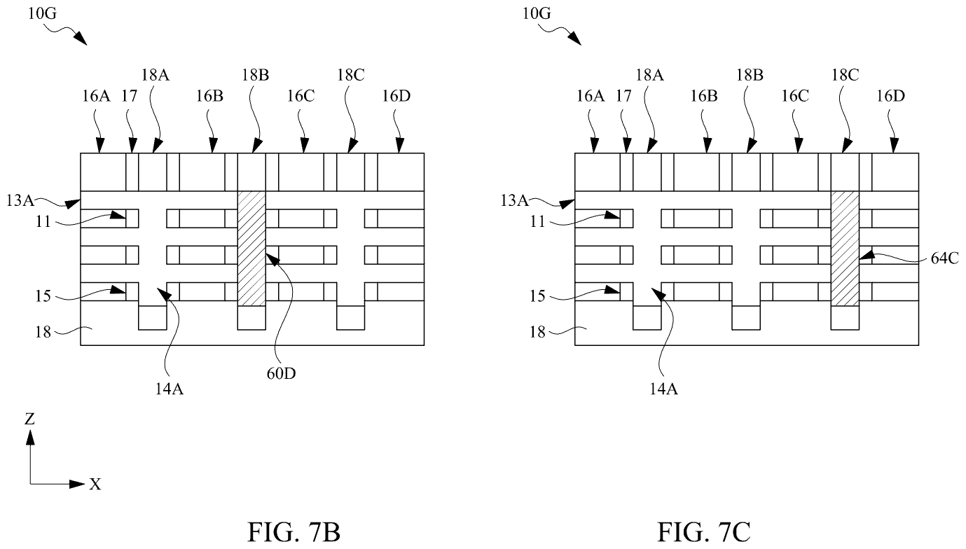

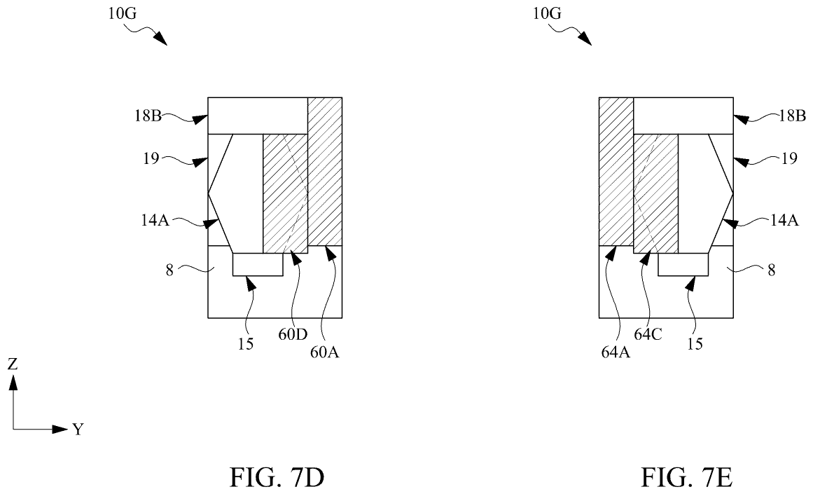

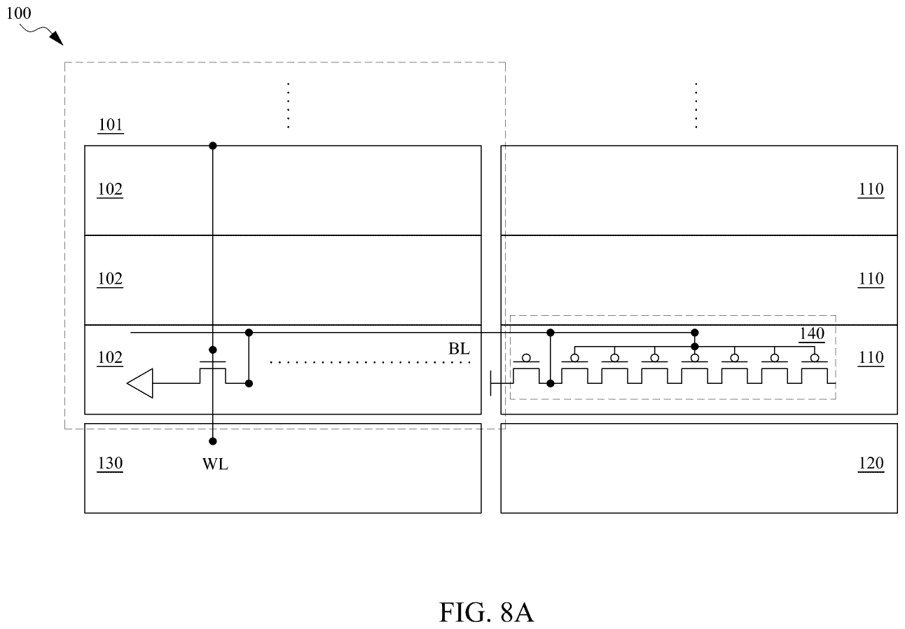

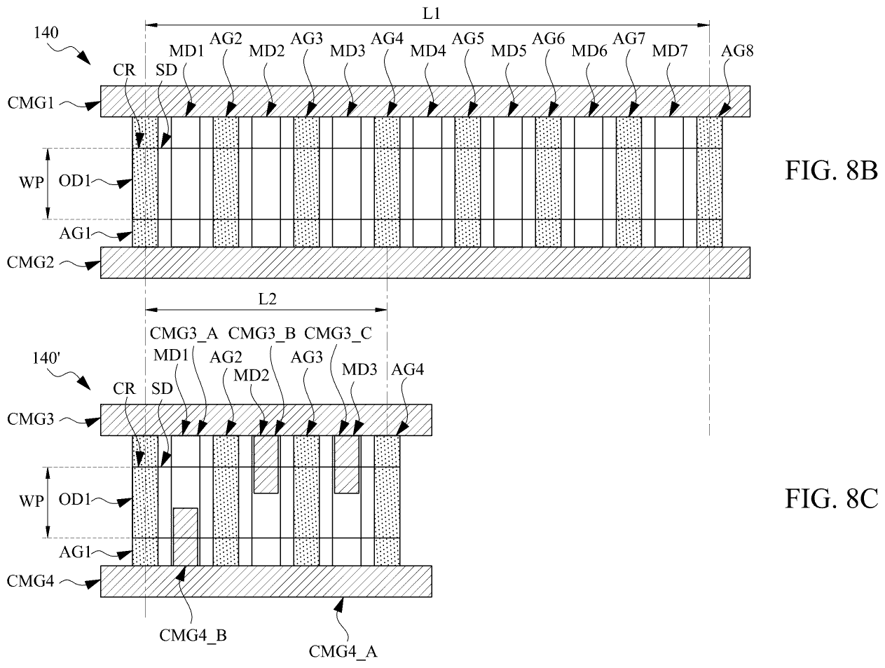

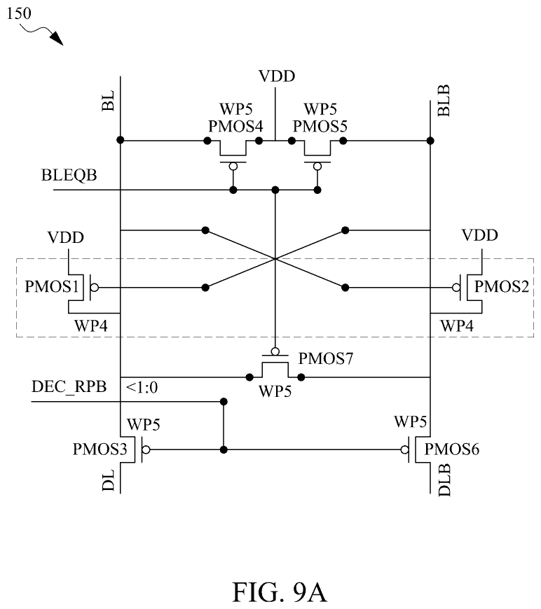

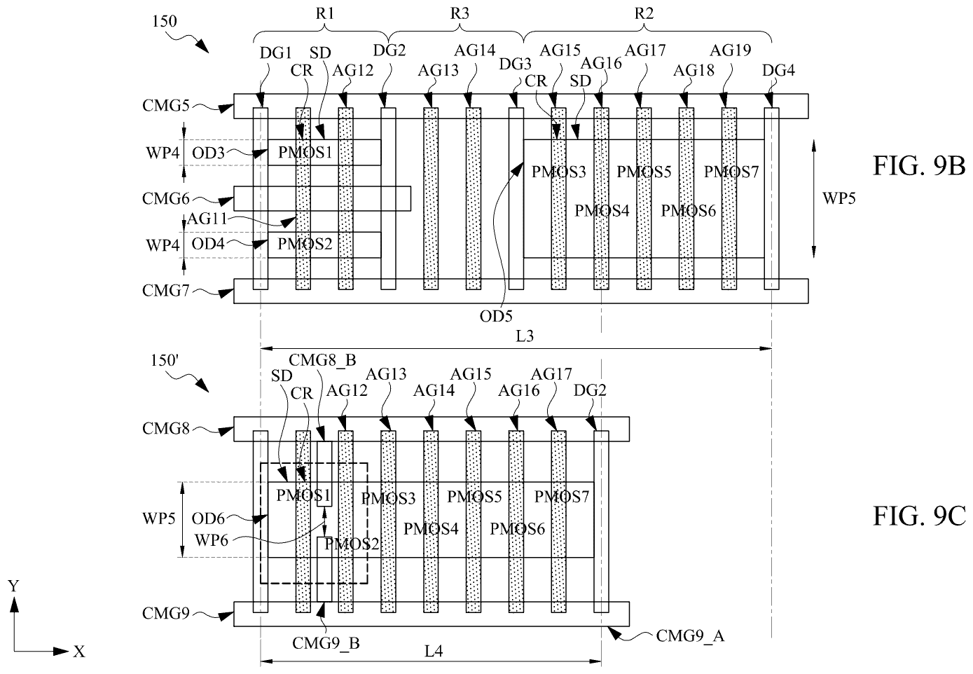

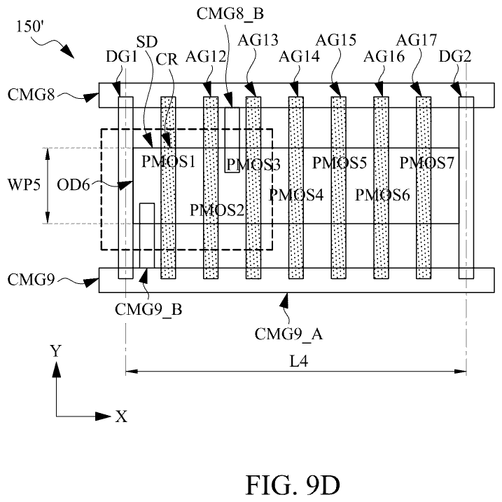

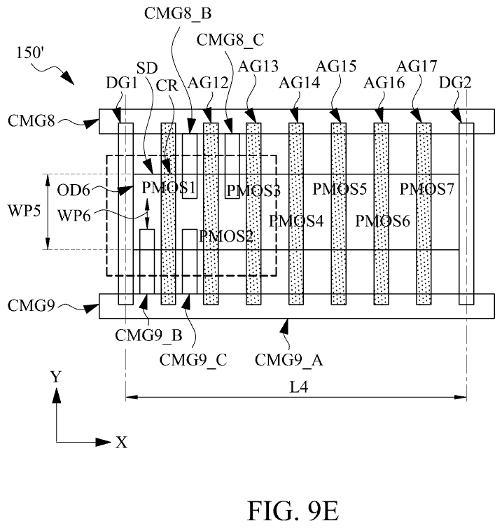

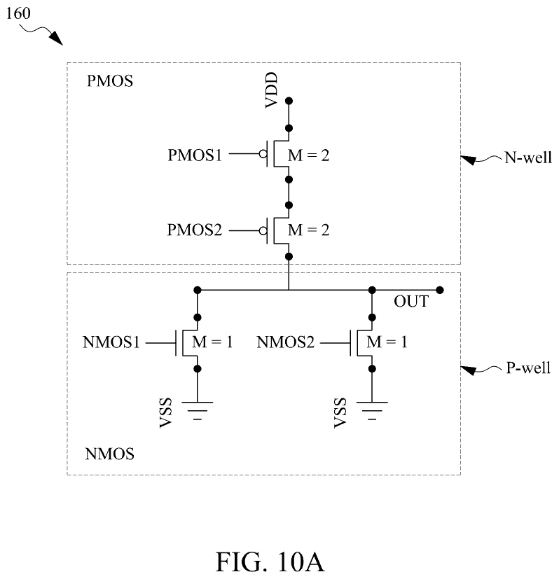

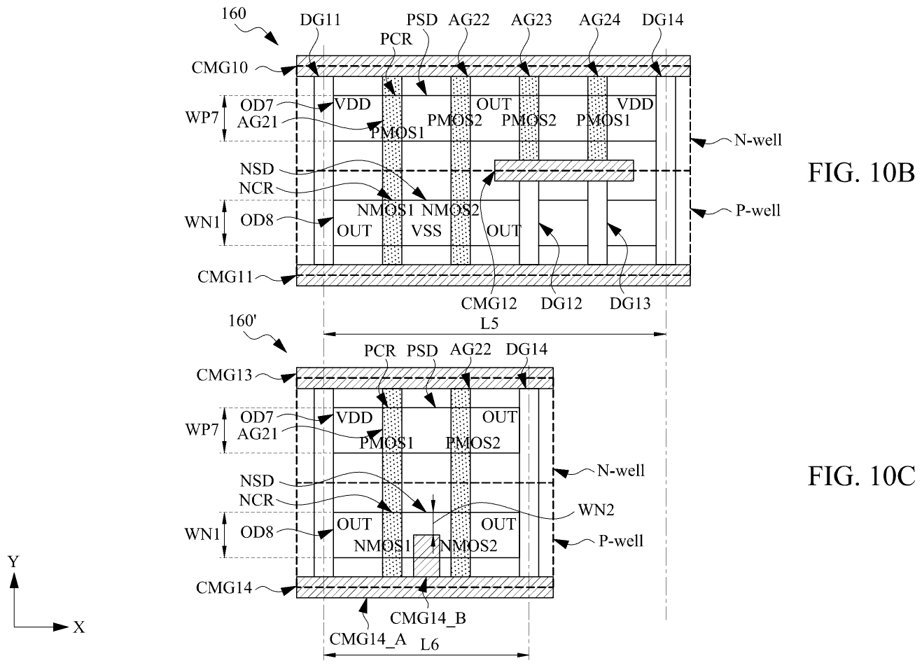

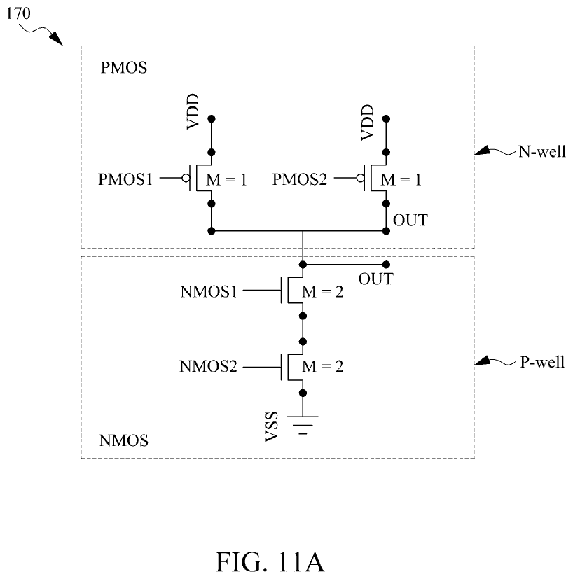

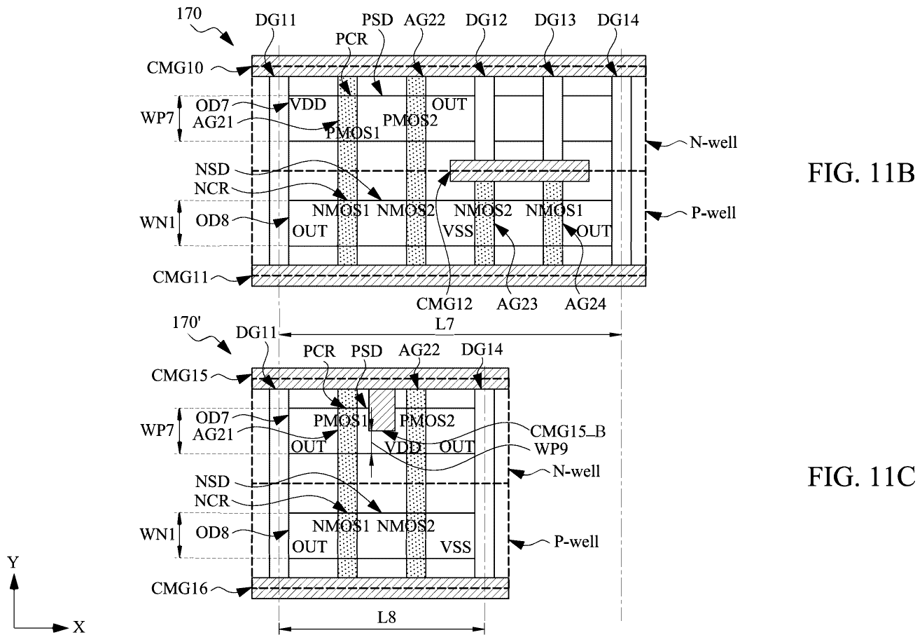

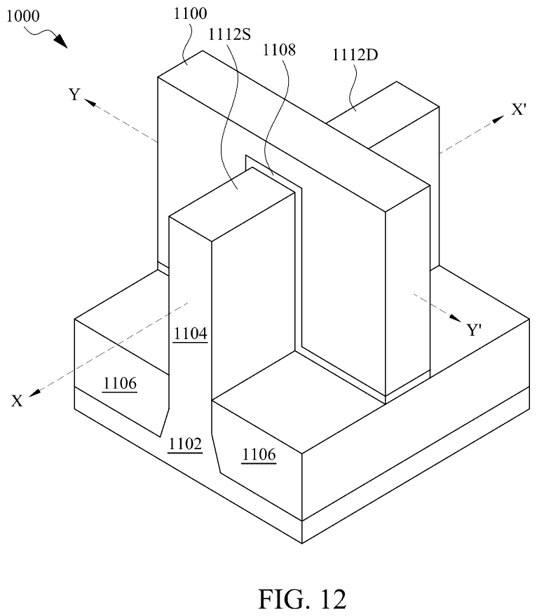

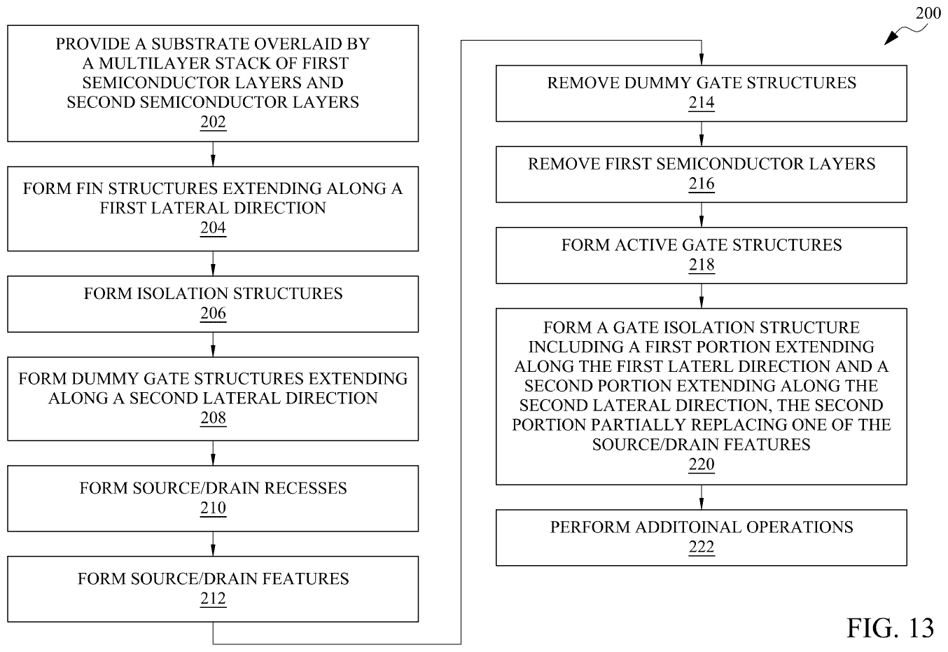

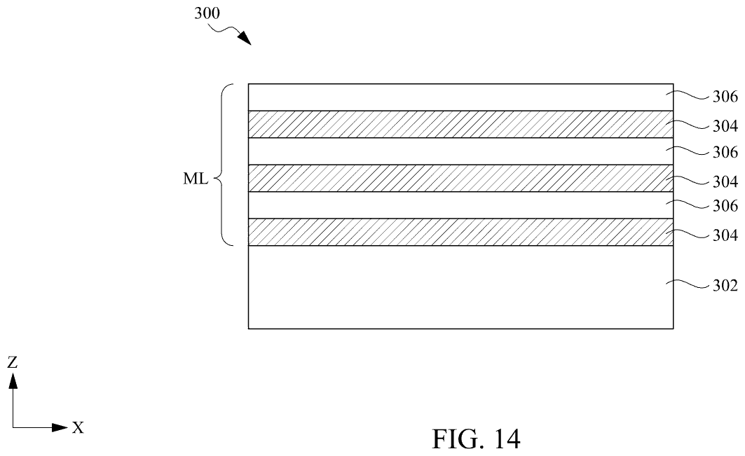

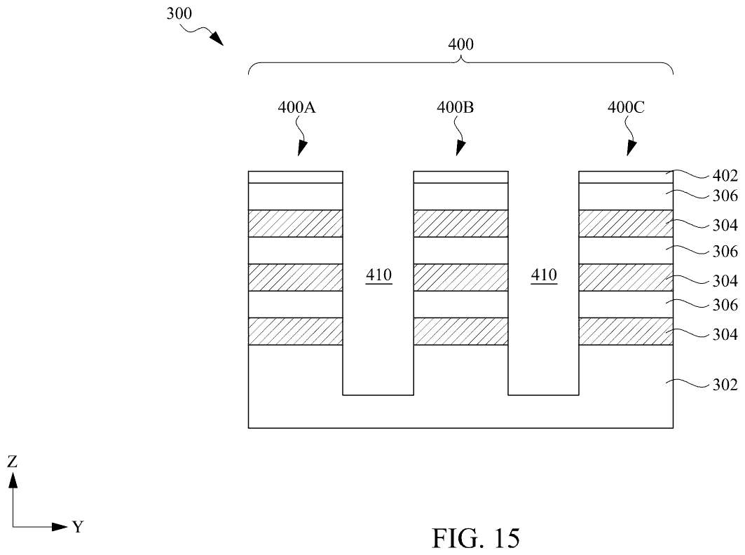

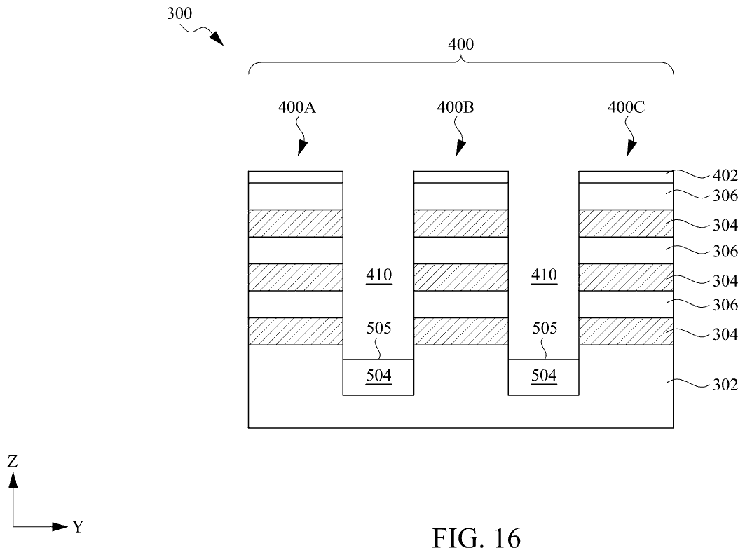

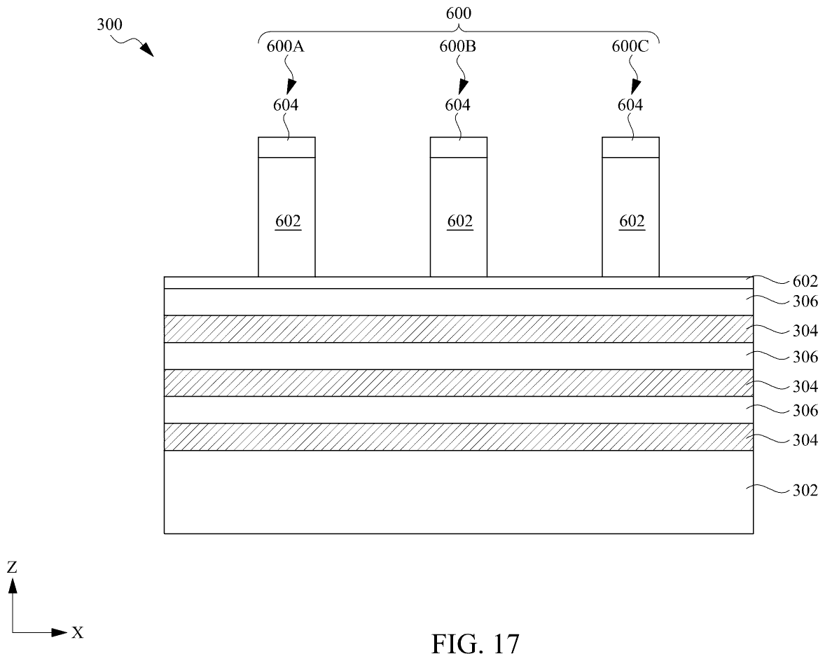

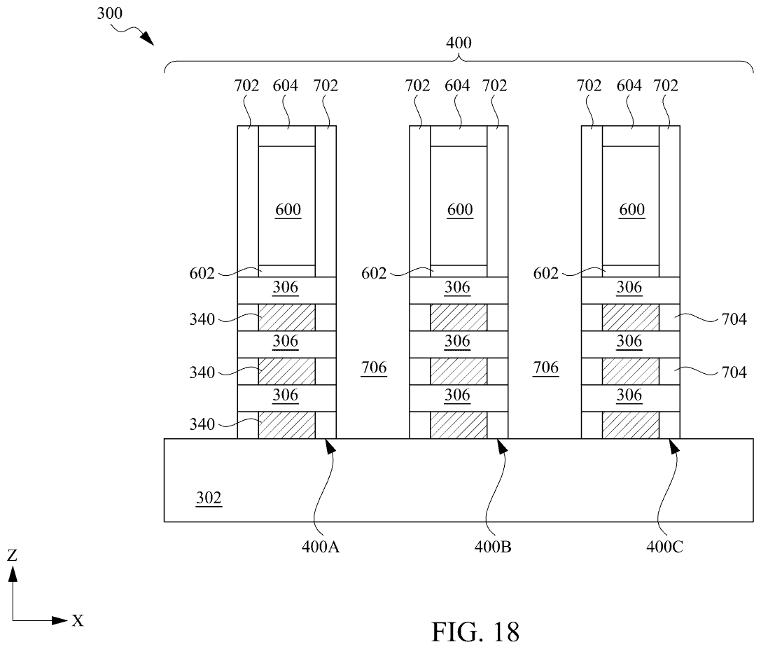

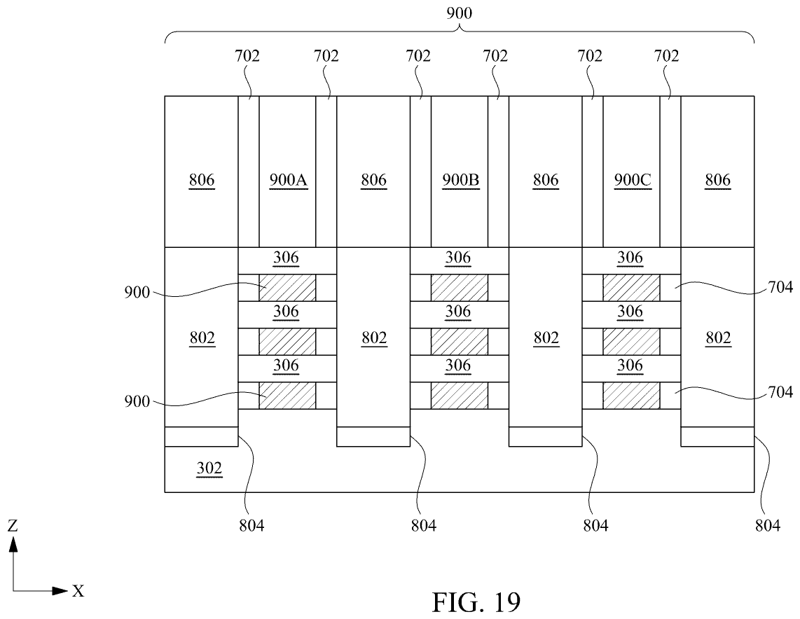

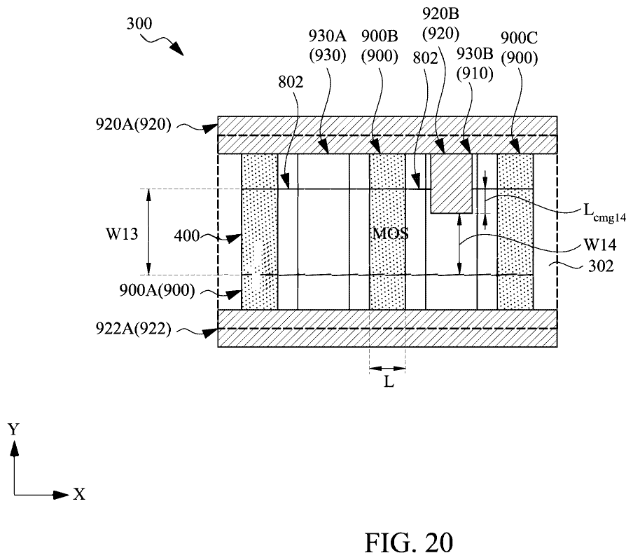

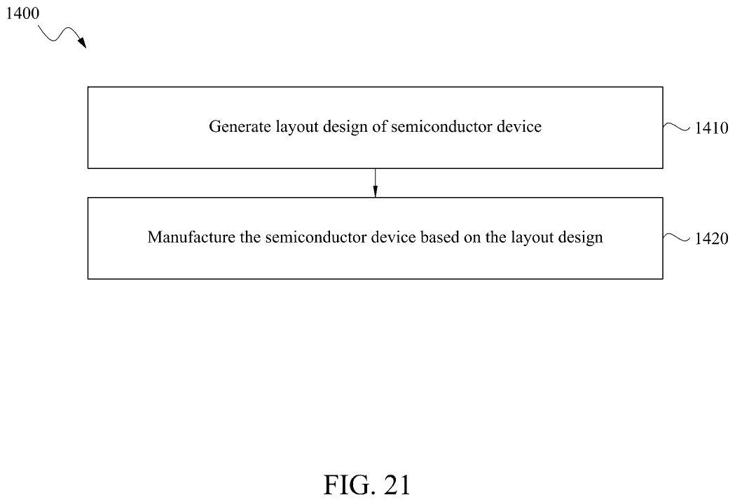

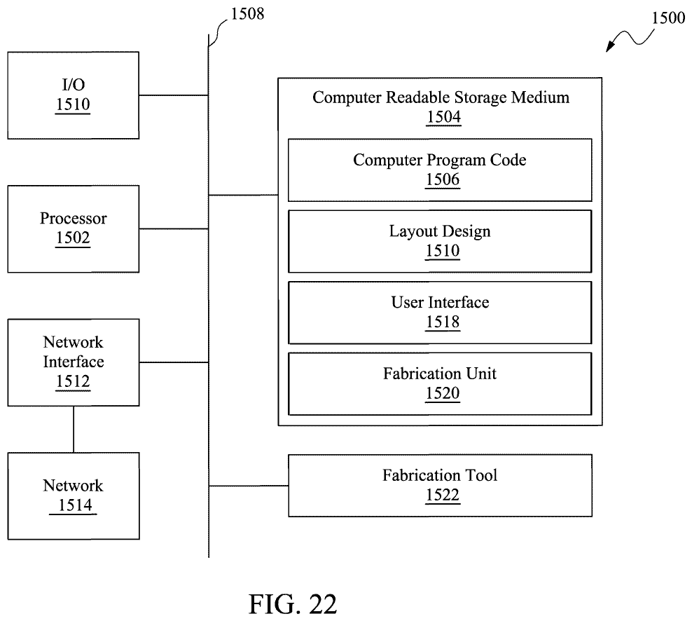

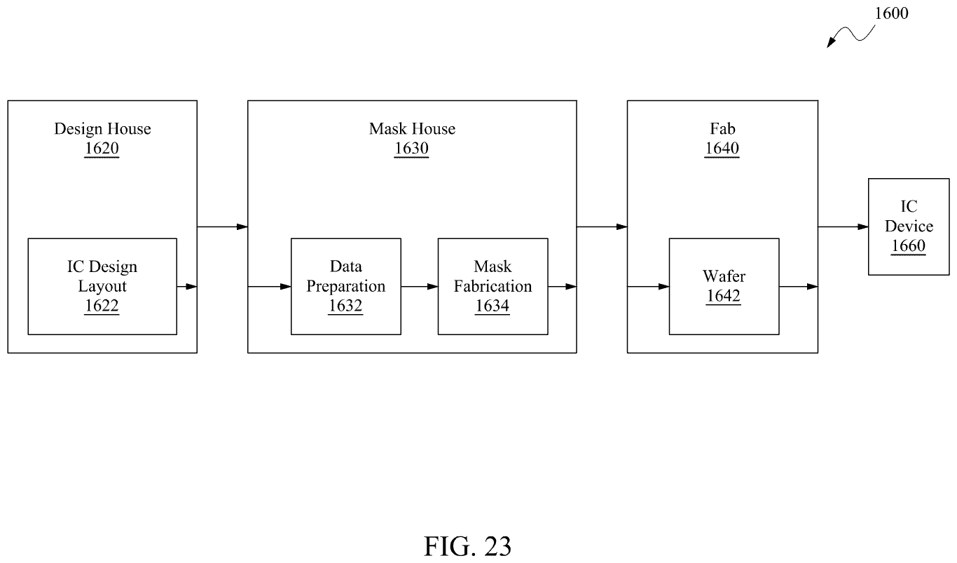

Referring to FIGS. 7A, 7B, 7C, 7D, and 7E, a semiconductor device 10G (hereafter referred to as device 10G) is provided. FIG. 7A depicts a top view of the device 10G, FIG. 7B depicts a cross-sectional view of the device 10G taken along line AA′, FIG. 7C depicts a cross-sectional view of the device 10G taken along line DD′, FIG. 7D depicts a cross-sectional view of the device 10G taken along line BB′, and FIG. 7E depicts a cross-sectional view of the device 10G taken along line CC′.

The device 10G includes components substantially similar to those of the device 10F, with the exception that the gate isolation structure 60 does not include the third portion 60C that extends from the first portion 60A towards the second one of the source/drain features 14A. The active region 12A engages the active gate structure 16C to form a fourth MOS device MOS4, with a pair of the source/drain features 14A straddling sidewalls of the active gate structure 16C. In the depicted embodiment, as the MOS1 and the MOS4 share a common source/drain feature 14A, a portion of which is replaced by the second portion 60B, the adjusted current I_{d_adj} of the MOS4 may be defined by Equation VIII above.

Examples of the concepts embodied in devices 10A-10G are further illustrated in FIGS. 8A-11C.

In one example, referring to FIGS. 8A, 8B, and 8C, a memory device 100 is provided. Referring to FIG. 8A, which depicts a schematic representation of the memory device 100, the memory device (or macro) 100 includes an input/output (I/O) circuit 110, a control logic circuit 120, a word line (WL) driver 130, and a memory array 101. The I/O circuit 110, the control logic circuit 120, and the WL driver 130 may be collectively referred to as a peripheral circuit of the memory device 100. The memory array 101 includes a plurality of bit cells 102 arranged in two- or three-dimensional arrays, where each bit cell 102 may include a static random-access memory (SRAM) cell, for example. Each of the bit cells 102 is accessible through a plural number of access lines, such as a corresponding word line and a corresponding pair of bit lines (BLs). Despite not being explicitly shown in FIG. 8A, the various components of the memory device 100 may be electrically (or operatively) coupled to each other and to the control logic circuit 120.

The WL driver 130, which may include a row decoder and a WL voltage supply unit, can be responsible for activating word lines within the memory array 101. The I/O circuit 110 is a hardware component that can access (e.g., read, program) each of bit cells 102 asserted through an area decoder, such as the row decoder and a column decoder. The control logic circuit 120 is a hardware component that controls various coupled components of the memory device 100 (e.g., the components 110, 120, and 130). In some embodiments, the control logic circuit 120 includes a BL controller (not depicted herein), where the BL controller can further include a keeper circuit 140 and a pre-charge circuit (not depicted herein). In various embodiments, the pre-charge circuit can utilize a pre-charging signal to pre-charge the BLs to a high logic state (e.g., VDD) during a phase when the memory array 101 is not being read or written; and the keeper circuit 140 can keep a voltage level present on the BLs to its supposed voltage level when the memory array 101 is being read, by supplying a keeper current.

In general, memory bit cells in a memory array may be coupled to a keeper circuit configured to assist in “keeping” bit lines charged to a voltage level if the bit lines are supposed to be charged to that voltage level. For example, when reading a logic 0 from a memory cell, the keeper circuit can keep the voltage level present on a bit line coupled to the memory cell to be substantially close to a voltage level corresponding to the logic 0; and when reading a logic 1 from the memory cell, the keeper circuit can keep the voltage level present on a bit line coupled to the memory cell to be substantially close to a voltage level corresponding to the logic 1. In the existing memory technologies, implementing such a keeper circuit typically includes electrically coupling a substantial number of PMOS transistors in series, which may disadvantageously lead to increased device area or footprint.

FIG. 8B depicts an example layout of the keeper circuit 140 according to FIG. 8A. The keeper circuit 140 includes a plurality of PMOS transistors, including PMOS1, PMOS2, PMOS3, PMOS4, PMOS5, and PMOS6, electrically coupled in series and provided on an active region OD1 (e.g., the active region 12A). Each of the PMOS1-PMOS6 includes a channel region CR (e.g., the nanostructures 13A) of the OD1 engaging an active gate structure AG2, AG3, AG4, AG5, AG6, and AG7, respectively, a pair of source/drain features SD (e.g., the source/drain features 14A) disposed in the OD1 and straddling sidewalls of each active gate structure AG.

The keeper circuit 140 depicted in FIG. 8B has a length L1 along the first lateral direction, where the length L1 is defined by 7 CPPs. The active region OD1 has a width WP along the second lateral direction. The keeper circuit 140 further includes gate isolation structures CMG1 and CMG2 extending along the first lateral direction and abutting opposite ends of each active gate structure AG. Each of the gate isolation structures CMG1 and CMG2 includes only a horizontal portion (e.g., the first portion 50A of the gate isolation structure 50) extending along the first lateral direction but not any transverse portion (e.g., the second portion 50B of the gate isolation structure 50). The gate isolation structures CMG1 and CMG2 (as well as the gate isolation structures described below) may be substantially similar to or the same as the gate isolation structures 50, 52, 60, 62, and 64 in composition as described herein. Still further, the keeper circuit 140 may include a plurality of source/drain contacts MD1, MD2, MD3, MD4, MD5, MD6, and MD7 each electrically coupled to one of the source/drain features SD and interposed between two adjacent active gate structures AG.

To operate the keeper circuit 140, the plurality of the PMOS transistors PMOS1-PMOS6 are electrically coupled in series to increase the length L1, resulting in a low current through the PMOS transistors PMOS1-PMOS6 in accordance with the mathematic expression of Equation I. However, this also increases the area occupied by the keeper circuit 140 (i.e., the device footprint). To reduce the device area without significantly impacting the device performance, referring to FIG. 8C, a modified keep circuit 140′ is provided. In this regard, a current I_{d} (e.g., a leakage current) of the circuit can be reduced (or kept at a minimum) by utilizing the two-dimensional gate isolation structures described herein without increasing the number of the PMOS transistors coupled in the circuit.

FIG. 8C depicts an example layout of the modified keeper circuit 140′ that is operatively equivalent to the keeper circuit 140 depicted in FIG. 8B but with area-saving benefit. In contrast to the structure of the keeper circuit 140, the modified keeper circuit 140′ includes gate isolation structures CMG3 and CMG4 each having a horizontal portion and at least one transverse portion that extends from the horizontal portion towards the source/drain features SD. For example, the gate isolation structure CMG3 includes a horizontal portion CMG3_A, a first transverse portion CMG3_B, and a second transverse portion CMG3_C. The transverse portions CMG3_B and CMG3_C each truncate or replace a portion of the source/drain features SD, thereby reducing the width WP of the active region OD1 to a width WP1 and WP2, respectively. Similarly, the gate isolation structure CMG4 includes a horizontal portion CMG4_A and a transverse portion CMG4_B such that the transverse portion CMG4_B also reduces the width WP to a width WP3 as depicted herein. By applying an expression similar to that of any of Equations III-IX, an adjusted current I_{d_adj} of the modified keeper circuit 140′, which is less than the current I_{d} of the keeper circuit 140, can be determined based on a resistance contribution of the first transverse portion CMG3_B (cmg7) of the gate isolation structure CMG3 to the source/drain feature SD of the transistor PMOS1, a resistance contribution of the second transverse portion CMG3_C (cmg8) of the gate isolation structure CMG3 to the source/drain feature SD of the transistor PMOS2, and a resistance contribution of the transverse portion CMG4_B (cmg9) of the gate isolation structure CMG4 to the source/drain feature SD of the transistor PMOS1, according to Equation X:

$${I}_{d \_ adj} = \frac{{V}_{e}}{{R}_{c h} + {R}_{S \_ cmg 8} + {R}_{D \_ cmg 7} + {R}_{S \_ cmg 9}} < {I}_{d} , \qquad ( X )$$

where the resistance R_{D_cmg7} increases with a decreased width WP2, the resistance R_{S_cmg8} increases with a decreased width WP3, and the resistance R_{S_cmg9} increases with a decreased width WP1.

Advantageously, by narrowing the width of the active region OD1 using the transverse portions of the gate isolation structures CMG3 and/or CMG4, a number of the PMOS transistors can be reduced in the modified keeper circuit 140, e.g., from six PMOS transistors to two PMOS transistors, leading to a reduction of a length of the circuit structure, e.g., from the length L1 of 7 CPPs to a length L2 of 3 CPPs as depicted in FIG. 8C, thus resulting in the area-saving benefit. In various embodiments, the extent of the reduction in the area occupied by the modified keeper circuit 140 depends on values of the widths WP1, WP2, and WP3, which may have the same or different values and may be adjusted independently by configuring the gate isolation structures CMP3 and CMP4. In some examples, the widths WP1, WP2, and WP3 may each be greater than 0 and less than the width WP.

In another example, referring to FIGS. 9A, 9B, 9C, 9D, and 9E, an embodiment of a portion of a peripheral circuit 150 (hereafter referred to as a portion 150) of a memory device is provided. FIG. 9A depicts an example circuit diagram of the portion 150 and FIG. 9B depicts an example layout of the portion 150 according to FIG. 9A. In some embodiments, referring to FIGS. 9A and 9B collectively, the portion 150 includes different device regions over which PMOS transistors such as PMOS1, PMOS2, PMOS3, PMOS4, PMOS5, PMOS6, and PMOS7, are configured with different dimensions (with respect to the active regions) and thus different current output capabilities. In some examples, the PMOS1 and PMOS2 are cross-coupled PMOS transistors configured to provide lower current output than the PMOS3-PMOS7. In some examples, the PMOS3 and PMOS4 are configured to control signals provided to data line DL and data line DLB. In some examples, the PMOS4 and PMOS5 are configured as a pre-charge circuit of the portion 150.

Specifically, in the depicted embodiment, the PMOS1 and PMOS2 are cross-coupled and provided in a first region R1 of the portion 150, and the PMOS3-PMOS7 are coupled in series and provided in a second region R2 of the portion 150. Referring to FIG. 9B, the first region R1 and the second region R2 are separated by a third region R3 along the first lateral direction, where the third region R3 is considered a dummy region or inactive region substantially free of any active regions OD and generally required to comply with specific design rules, for example. Adjacent regions of the portion 150 are separated by active region isolation structures DG1, DG2, DG3, and DG4 each extending along the second lateral direction and spaced from one another along the first lateral direction. The active region isolation structures DG1-DG4 (and any additional active region isolation structures described below) may include any suitable dielectric material, such as silicon oxide, silicon nitride, other suitable materials, or combinations thereof. For purposes of simplicity, certain components of the portion 150, such as source/drain contacts of the various PMOS transistors, are omitted in FIGS. 9A-9E.

The first region R1 includes a first active region OD3 and a second active region OD4 each extending along the first lateral direction and spaced from one another along the second lateral direction. Each of the PMOS1 and PMOS2 includes a channel region CR (e.g., the nanostructures 13A) of their respective OD engaging an active gate structure AG11 and AG12, respectively, a pair of source/drain features SD (e.g., the source/drain features 14A) disposed in the respective active regions ODs and straddling sidewalls of the respective active gate structures AG. The active regions OD3 and OD4 each have a width WP4 along the second lateral direction.

The second region R2 includes a third active region OD5 extending along the first lateral direction and spaced from each of the active regions OD3 and OD4 along the first lateral direction. Each of the PMOS3-PMOS7 includes a channel region CR (e.g., the nanostructures 13A) of the third active region OD5 engaging an active gate structure AG15, AG16, AG17, AG18, and AG19, respectively, a pair of source/drain features SD (e.g., the source/drain features 14A) disposed in the third active region OD5 and straddling sidewalls of the respective active gate structures AG. The third active regions OD5 has a width WP5 along the second lateral direction, where the width WP5 is greater than the width WP4.

The portion 150 includes gate isolation structures CMG5 and CMG7 extending along the first lateral direction and abutting opposite ends of each active gate structure AG across the regions R1-R3. The portion 150 further includes an additional isolation structure CMG6 disposed between the active regions OD3 and OD4 along the second lateral direction. Each of the gate isolation structures CMG5-CMG7 includes only a horizontal portion (e.g., the first portion 50A of the gate isolation structure 50) extending along the first lateral direction but not any transverse portion (e.g., the second portion 50B of the gate isolation structure 50).

In order to isolate the various PMOS transistors having different active region dimensions and maintain certain device density in compliance with design rules, the third region R3 is included in the portion 150 with additional active gate structures AG13 and AG14 (though no active devices are formed therefrom) and active region isolation structures DG2 and DG3 disposed thereover, thereby increasing the area or footprint of the portion 150. In some examples, as depicted in FIG. 9B, the area occupied by the portion 150 is defined by a minimum length L3 of 12 CPPs.

To reduce the device area without significantly impacting the device performance, referring to FIG. 9C, a modified portion 150′ is provided. In this regard, a current I_{d} of the circuit can be reduced (or kept at a minimum) by utilizing the two-dimensional gate isolation structures described herein without increasing the number of the PMOS transistors coupled in the circuit. Specifically, FIG. 8C depicts an example layout of the modified portion 150′ that is operatively equivalent to the portion 150 depicted in FIG. 9B but with area-saving benefit. In contrast to the structure of the portion 150, the modified portion 150′ includes a single active region OD6 having the width WP5. As such, a portion of the active region OD6, as shown outside the dashed enclosure, is suitable for forming the PMOS3-PMOS7 having the desired functions according to FIGS. 9A and 9B.

To accommodate forming the cross-coupled PMOS1 and PMOS2 that require a lower current for operation, the modified portion 150′ is configured to include gate isolation structures CMG8 and CMG9 each having a horizontal portion and at least one transverse portion that extends from the horizontal portion towards the source/drain features SD. In some embodiments, the gate isolation structure CMG8 includes a horizontal portion CMG8_A and a transverse portion CMG8_B, and the gate isolation structure CMG9 includes a horizontal portion CMG9_A and a transverse portion CMG9_B. Each horizontal portion extends along the first lateral direction and each transverse portion extends along the second lateral direction from the corresponding horizontal portion.

In this regard, the transverse portion CMG8_B and the transverse portion CMG9_B each truncate or replace a portion of the same source/drain feature SD in an active region OD6 that is shared by the PMOS1 and PMOS2, thereby reducing the width WP5 of the active region OD6 to a width WP6. By applying an expression similar to that of any of Equations III-IX, an adjusted current I_{d_adj} of the modified portion 150′, which is less than the current I_{d}, can be determined based on a resistance contribution of the transverse portion CMG8_B (cmg10) of the gate isolation structure CMG8 to the shared source/drain feature SD (e.g., a shared drain feature) of the PMOS1/PMOS2 and a resistance R_{cmg11} of the transverse portion CMG9_B (cmg11) of the gate isolation structure CMG3 to the same shared source/drain feature SD of the PMOS1/PMOS2 (e.g., the common drain feature), according to Equation XI:

$${I}_{d \_ adj} = \frac{{V}_{e}}{{R}_{c h} + {R}_{S} + {R}_{{D}_{c m g 10 + c m g 11}} + {R}_{S}} < {I}_{d} , \qquad ( XI )$$

where the resistance R_{D_cmg10+cmg11} increases with a decreased width WP6. In this regard, the adjusted current I_{d_adj} may be tuned by adjusting the width WP6, i.e., adjusting the resistance R_{D_cmg10+cmg11}. In some embodiments, adjusting the resistance R_{D_cmg10+cmg11} may be achieved by adjusting a length of one or both of the transverse portions CMG8_B and CMG9_B that extend into the source/drain feature SD, as described in detail above. In the present embodiments, the widths WP6 is greater than 0 and less than the width WP5.

In some embodiments, the positions of one or more of the transverse portion(s) of the gate isolation structures CMG8 and CMG9 are varied to obtain the adjusted current I_{d_adj} as described above with respect to FIG. 9C. For example, referring to FIG. 9D, another example embodiment of the modified portion 150′ includes components substantially similar to those depicted in FIG. 9C with the exception that the transverse portions CMG8_B and CMG9_B are positioned such that they truncate or replace a portion of two different source/drain features SD in the active region OD6. The adjusted current I_{d_adj} can be determined based on the resistance introduced by the transverse portions CMG8_B and CMG9_B in a manner similar to that described above with respect to FIG. 9C.

In some embodiments, referring to FIG. 9E, another example embodiment of the modified portion 150′ includes components substantially similar to those depicted in FIG. 9C with the exception that the gate isolation structure CMG8 includes two transverse portions CMG8_B and CMG8_C extending along both sides of the active gate structure AG12, and the gate isolation structure CMG9 includes two transverse portions CMG9_B and CMG9_C extending along both sides of the active gate structure AG11. In this regard, a portion of each of the source/drain features S/D of the PMOS1 and PMOS in the active region OD6 is replaced with a portion of a corresponding one of the transverse portions CMG8_B, CMG8_C, CMG9_B, and CMG9_C. The adjusted current I_{d_adj} can be determined based on the resistance introduced by the transverse portions CMG8_B, CMG8_C, CMG9_B, and CMG9_C in a manner similar to that described above with respect to FIG. 9C.

Advantageously, by narrowing the width of a portion of the active region OD6 using the transverse portions of the gate isolation structures CMG8 and/or CMG9, PMOS transistors having different functions and outputting different levels of current may be formed in the same active region, thereby obviating the need for a dummy region (e.g., the third region R3). Accordingly, a length of the circuit structure is reduced, e.g., from the length L3 of 12 CPPs to a length L4 of 8 CPPs as depicted in each of FIGS. 9C-9E, resulting in the area-saving benefit.

In another example, referring to FIGS. 10A, 10B, and 10C, an embodiment of a logic circuit 160 (hereafter referred to as a circuit 160) is provided. FIG. 10A depicts an example circuit diagram of the circuit 160 and FIG. 10B depicts an example layout of the circuit 160 according to FIG. 10A. In some embodiments, the circuit 160 represents a NOR logic circuit.

Referring to FIGS. 10A and 10B collectively, the circuit 160 includes at least an active region OD7 and an active region OD8 each extending along the first lateral direction and spaced from one another along the second lateral direction. The active region OD7 is formed in an N-well with a width WP7 along the second lateral direction and is configured to provide a plurality of PMOS transistors PMOS1 and PMOS2, while the active region OD8 is formed in a P-well with a width WN1 along the second lateral direction and is configured to provide a plurality of NMOS transistors NMOS1 and NMOS2. The width WP7 and the width WN1 may be the same or different. In the depicted embodiment, the PMOS1 and PMOS2 are electrically coupled in series as a pair and two pairs of the PMOS1 and PMOS2 are electrically coupled in parallel. The PMOS transistors are subsequently coupled to the NMOS1 and NMOS2, which are electrically coupled in parallel.

Each of the PMOS1 and PMOS2 includes a channel region PCR (e.g., the nanostructures 13A) in the active region OD7 engaging active gate structures AG21, AG22, AG 23, and AG24, respectively, a pair of source/drain features PSD (e.g., the source/drain features 14A) straddling sidewalls of the respective active gate structures AG. Each of the NMOS1 and NMOS2 includes a channel region NCR (e.g., the nanostructures 13A) in the active region OD8 engaging active gate structures AG21 and AG22, respectively, a pair of source/drain features NSD (e.g., the source/drain features 14A) straddling sidewalls of the respective active gate structures AG.

Referring to FIG. 10B, the circuit 160 includes gate isolation structures CMG10 and CMG11 extending along the first lateral direction and abutting opposite ends of each active gate structure AG. The circuit 160 further includes an additional isolation structure CMG12 disposed between the active regions OD7 and OD8 along the second lateral direction. Each of the gate isolation structures CMG10-CMG12 includes only a horizontal portion (e.g., the first portion 50A of the gate isolation structure 50) extending along the first lateral direction but not any transverse portion (e.g., the second portion 50B of the gate isolation structure 50).

The circuit 160 may include active region isolation structures DG11, DG12, DG13, and DG14 each extending along the second lateral direction and spaced from one another along the first lateral direction. The active region isolation structures DG11-DG14 may be configured to separate adjacent device regions along the first lateral direction. In the depicted embodiment, the active region isolation structures DG12 and DG13 are formed over the active region OD8 and extend from the active gate structures AG23 and AG24, respectively, along the second lateral direction. For purposes of simplicity, certain components of the circuit 160, such as source/drain contacts of the various PMOS and NMOS transistors, are omitted in FIGS. 10B and 10C.

For embodiments depicted in FIGS. 10A and 10B, multiple pairs of the PMOS1 and PMOS2 (two pairs are herein depicted) are electrically coupled in parallel to achieve a higher I_{d_pmos} so as to match a current I_{d_nmos} of the NMOS1 and NMOS2. In the depicted embodiments, the current I_{d_nmos} is equivalent to twice the current through each pair of the PMOS1 and PMOS2. This arrangement thus requires at least four active gate structures AG21-AG24 over the active region OD7, resulting in a length L5 of the circuit 160 to be at least 5 CPPs and the active region isolation structures DG12 and DG13 occupying extra area not contributing to active device operations. Accordingly, it may be desirable to reduce the device area without significantly impacting the device performance.

Referring to FIG. 10C, a modified circuit 160′ is provided. In some embodiments, the current I_{d_nmos} of the modified circuit 160′ for the NMOS transistors can be reduced by utilizing the two-dimensional gate isolation structure described herein without increasing the number of the PMOS transistors coupled in the circuit. Specifically, FIG. 10C depicts an example layout of the modified circuit 160′ that is operatively equivalent to the circuit 160 depicted in FIG. 10B but with area-saving benefit. The modified circuit 160′ includes the same active regions OD7 and OD8, with only one pair of PMOS1 and PMOS2 formed over the active region OD7, which is a reduction from the two pairs depicted in the circuit 160, and with the NMOS1 and NMOS2 being formed over the active region OD8 in the same arrangement as that of the circuit 160.

To accommodate the reduction in the number of the serially coupled PMOS1 and PMOS2, which corresponds to a lower current for operation of the parallel coupled NMOS1 and NMOS2, the modified circuit 160′ is configured to include gate isolation structures CMG13 and CMG14. Each of the gate isolation structures CMG13 and CMG14 includes a horizontal portion, where the gate isolation structure CMG14 also includes one transverse portion that extends from the horizontal portion towards the source/drain features NSD. In some embodiments, the gate isolation structure CMG14 includes a horizontal portion CMG14_A and a transverse portion CMG14_B, and the gate isolation structure CMG13 includes a horizontal portion CMG13_A. Each horizontal portion extends along the first lateral direction and each transverse portion extends along the second lateral direction from the corresponding horizontal portion.

In this regard, the transverse portion CMG14_B truncates or replaces a portion of the shared source/drain feature NSD in the active region OD8 and between the NMOS1 and the NMOS2, thereby reducing the width WN1 of the active region OD8 to a width WN2. By applying the expression similar to that of any of Equations III-IX, an adjusted current I_{d_adj_nmos} of the parallel coupled NMOS1 and NMOS2, which is less than the current I_{d} nmos, can be determined based on a resistance contribution of the transverse portion CMG14_B (cmg12) of the gate isolation structure CMG14 to the shared source/drain feature NSD (e.g., a shared drain feature) of the NMOS1/NMOS2, according to Equation XII:

$${I}_{d \_ adj \_ nmos} = \frac{{V}_{e}}{{R}_{c h} + {R}_{S} + {R}_{{D}_{c m g 12}} + {R}_{S}} < {I}_{d \_ nmos} , \qquad ( XII )$$

where the resistance R_{D_cmg12} increases with a decreased width WN2. In this regard, the adjusted current I_{d_adj_nmos} may be tuned by adjusting the width WN2, i.e., adjusting the resistance R_{D_cmg12}. In some embodiments, adjusting the resistance R_{D_cmg12} may be achieved by adjusting a length of the transverse portion CMG14_B extending into the source/drain feature NSD, as described in detail above. In the present embodiments, the width WN2 is greater than 0 and less than the width WN1.

Advantageously, by narrowing the width of a portion of the active region OD8 using the transverse portion of the gate isolation structure CMG14, which may reduce the width WN2 to ½WN1 as depicted herein, the current through the NMOS1 and NMOS2 is reduced by about 50%, effectively lowering the required level of current provided by the PMOS transistors. In this regard, the number of the PMOS1 and PMOS1 coupled to the NMOS transistors is correspondingly reduced by about 40% from the length L5 of 5 CPPs to a length L6 of 3 CPPs as depicted in FIG. 10C, for example, resulting in the area-saving benefit.

In yet another example, referring to FIGS. 11A, 11B, and 11C, an embodiment of a logic circuit 170 (hereafter referred to as a circuit 170) is provided. FIG. 11A depicts an example circuit diagram of the circuit 170 and FIG. 11B depicts an example layout of the circuit 170 according to FIG. 11A. In some embodiments, the circuit 170 represents a NAND logic circuit.

Referring to FIG. 11B, the circuit 170 is similar to the circuit 160 with the exception that, instead of having two pairs of serially coupled PMOS1 and PMOS2 formed over the active region OD7 and coupled to a pair of parallel coupled NMOS1 and NMOS2, which is formed over the active region OD8, the circuit 170 includes a pair of parallel coupled PMOS1 and PMOS formed over the active region OD7 and coupled to two pairs of serially coupled NMOS1 and NMOS2, which are formed over the active region OD8. In this regard, the active region isolation structures DG12 and DG13 are formed over the active region OD7 and the active gate structures AG23 and AG24 are formed over the active region OD8, resulting in the second pair of the serially coupled NMOS1 and NMOS2.

For embodiments depicted in FIGS. 11A and 11B, two pairs of the NMOS1 and NMOS2 are electrically coupled in parallel to achieve a higher I_{d_nmos} so as to match a current I_{d_pmos} of the PMOS1 and PMOS2. In the depicted embodiments, the current I_{d_pmos} is equivalent to twice the current through each pair of the NMOS1 and NMOS2. This arrangement thus requires at least four active gate structures AG21-AG24 over the active region OD8, resulting in the length L7 of the circuit 170 to be at least 5 CPPs and the active region isolation structures DG12 and DG13 occupying extra area not contributing to active device operations. Accordingly, it may be desirable to reduce the device area without significantly impacting the device performance.

Referring to FIG. 11C, an example layout of a modified circuit 170′ is provided. In some embodiments, the modified circuit 170′ is operatively equivalent to the circuit 170 depicted in FIG. 11B but with area-saving benefit, similar to the embodiment depicted in FIGS. 10A-10C. For example, the modified circuit 170′ includes the same active regions OD7 and OD8, with only one pair of NMOS1 and NMOS2 formed over the active region OD8, which is a reduction from the two pairs depicted in the circuit 170, and with the PMOS1 and PMOS2 being formed over the active region OD7 in the same arrangement as that of the circuit 170.

To accommodate the incorporation of only one pair of the serially coupled NMOS1 and NMOS2, which corresponds to a lower current for operation of the parallel coupled PMOS1 and PMOS2, the modified circuit 170′ is configured to include gate isolation structures CMG15 and CMG16 each having a horizontal portion, where the gate isolation structure CMG15 also includes one transverse portion that extends from the horizontal portion towards the source/drain features NSD. In some embodiments, the gate isolation structure CMG 15 includes a horizontal portion CMG15_A and a transverse portion CMG15_B, and the gate isolation structure CMG16 includes a horizontal portion CMG16_A. Each horizontal portion extends along the first lateral direction and each transverse portion extends along the second lateral direction from the corresponding horizontal portion.

In this regard, the transverse portion CMG15_B truncates or replaces a portion of the shared source/drain feature PSD in the active region OD7 and between the PMOS1 and the PMOS2, thereby reducing the width WP7 of the active region OD7 to a width WP9. By applying the expression similar to that of any of Equations III-VI, an adjusted current I_{d_adj_pmos} of the parallel coupled PMOS1 and PMOS2, which is less than the current I_{d_pmos}, can be determined based on a resistance contribution of the transverse portion CMG15_B (cmg13) of the gate isolation structure CMG15 to the shared source/drain feature PSD (e.g., a shared drain feature) according to Equation XIII:

$${I}_{d \_ adj \_ pmos} = \frac{{V}_{e}}{{R}_{c h} + {R}_{S} + {R}_{{D}_{c m g 13}} + {R}_{S}} < {I}_{d \_ pmos} , \qquad ( XIII )$$

where the resistance R_{D_cmg13} increases with a decreased width WP9. In this regard, the adjusted current I_{d_adj_pmos} may be tuned by adjusting the width WP9, i.e., adjusting the resistance R_{D_cmg13}. Similar to the embodiment depicted in FIGS. 10A-10C, adjusting the resistance R_{D_cmg_13} may be achieved by adjusting a length of the transverse portion CMG15_B extended into the source/drain feature PSD, as described in detail above. In the present embodiments, the width WP9 is greater than 0 and less than the width WP7.

Advantageously, by narrowing the width of a portion of the active region OD7 using the transverse portion of the gate isolation structure CMG15, the current through the PMOS1 and PMOS2 is reduced by about 50%, for example, effectively lowering the required level of current provided by the NMOS transistors. In this regard, the number of the pairs of the NMOS1 and NMOS1 required to be coupled to the PMOS transistors is correspondingly reduced by about 40%, for example, from the length L7 of 5 CPPs to a length L8 of 3 CPPs as depicted in FIG. 11C, resulting in the area-saving benefit.

In yet another example, the present disclosure provides methods of tuning a rising slew or a falling slew of different MOS transistors in various applications. For example, by reducing current through NMOS transistors, the rising slew of the NMOS transistors, which is related to a rate at which the current rises (to a set level, for example), can be improved. Analogously, by reducing current through PMOS transistors, the falling slew of the NMOS transistors, which is related to a rate at which the current falls (to a set level, for example), can be improved.

FIG. 12 illustrates a three-dimensional perspective view of an example semiconductor device 1000, in accordance with various embodiments. The device 1000 may be similar to any of the MOS devices depicted in FIGS. 1A-11C. The semiconductor device 1100 includes a substrate 1102 and a fin 1104 (alternatively referred to as a fin structure 1104 or an active region 1104) protruding from the substrate 1102 along the vertical direction (e.g., the Z axis). In some embodiments, the fin 1104 includes a single layer of semiconductor material. In some embodiments, the fin 1104 includes a plurality of semiconductor layers (e.g., nanosheets, nanorods, etc.) stacked along the vertical direction. Isolation regions 1106 are formed on opposing sides of the fin 1104, with the fin 1104 protruding above the isolation regions 1106. A gate dielectric layer 1108 is along sidewalls and over a top surface of the fin 1104, and a gate electrode layer 1110 is over the gate dielectric layer 1108, which together form a gate structure. In some embodiments, lower portions of the gate structure are interleaved with (i.e., arranged in an alternate pattern with) the plurality of semiconductor layers along the vertical direction, rendering the semiconductor device 1000 a multi-gate device, such as a GAA device. Source feature 1112S and drain feature 1112D (collectively referred to as source/drain features 1112S/D) are in (or extended from) the fin 1104 and on opposing sides of the gate structure. FIG. 12 is provided as a reference to illustrate a number of cross-sections in subsequent figures of a similar semiconductor device 300 (hereafter referred to as a device 300). For example, cross-sectional views taken along line X-X′ are along a longitudinal axis of the fin 1104 and in a direction of, for example, a current flow between the source/drain features 1112S/D. Cross-sectional views taken along line Y-Y′ are perpendicular to the cross-section X-X′ and along a longitudinal axis of the gate structure that includes the gate dielectric layer 1108 and the gate electrode layer 1110. Subsequent figures refer to these reference cross-sections for clarity.

FIG. 13 illustrates a flow chart of an example method 200 for making the device 300 in accordance with some embodiments. It should be noted that the method 200 is merely an example and is not intended to limit the present disclosure. Accordingly, it is understood that additional steps/operations may be provided before, during, and after the method 200 of FIG. 13, and that some other operations may only be briefly described herein. Various fabrication stages of the method 200 may be associated with cross-sectional views of the device 300 taken along a line equivalent to the line X-X′ of FIG. 12 (see FIGS. 14 and 17-19), with cross-sectional views of the device 300 taken along a line equivalent to the line Y-Y′ of FIG. 12 as (see FIGS. 15 and 16), and with a top view of the device 300 (see FIG. 20), which will be described in further detail below.

In brief overview, referring to FIG. 13, the device 300 may be formed by implementing operations 202 to 226, according to some embodiments. For example, the method 200 begins with operation 202 of providing a substrate overlaid by a multilayer stack of first semiconductor layers interleaved with second semiconductor layers. The method 200 proceeds to operation 204 of forming fin structures in the multilayer stack protruding from the substrate and extending along the first lateral direction. The method 200 proceeds to operation 206 of forming isolation structures over the substrate and adjacent to the fin structures. The method 200 proceeds to operation 208 of forming dummy gate structures extending along the second lateral direction over the fin structures. Next, the method 200 proceeds to operation 210 of forming source/drain recesses adjacent to each dummy gate structure. The method 200 proceeds to operation 212 of forming source/drain features to fill the source/drain recesses. The method 200 proceeds to operation 214 of removing the dummy gate structures. Next, the method 200 proceeds to operation 216 of removing the first semiconductor layers. The method 200 proceeds to operation 218 of forming active gate structures in place of the dummy gate structures and the first semiconductor layers. The method 200 then proceeds to operation 220 of forming a gate isolation structure that includes a first portion that extends along the first lateral direction and a second portion that extends along the second lateral direction, where the second portion partially replacing one of the source/drain features. The method 200 thereafter proceeds to operation 222 of performing any additional operations to complete fabrication of the device 300.

Referring to FIGS. 13 and 14, a substrate 302 is provided in the device 300 at the operation 202. In some embodiments, the substrate 302 is substantially similar to or the same as the substrate 8 described herein. The substrate 302 is overlaid with a multilayer structure (ML) of a number of first semiconductor layers 304 interleaved with a number of second semiconductor layers 306. In other words, the first semiconductor layers 304 and the second semiconductor layers 306 are alternatingly stacked as the ML on a top surface of the substrate 302. It should be understood that the device 300 can include any number of first semiconductor layers 304 and any number of second semiconductor layers 306 (which serve as channel layers), with either one of them being the topmost layer, while remaining within the scope of the present disclosure.

The semiconductor layers 304 and 306 have different compositions. In various embodiments, the semiconductor layers 304 and 306 have compositions that provide for different oxidation rates and/or different etch selectivity between the layers. In the present embodiments, the first semiconductor layers 304 include silicon germanium (Si₁₋ₓGeₓ), and the second semiconductor layers 306 include silicon (Si). In some embodiments, the second semiconductor layers 306 are substantially similar to or the same as the nanostructures 13A (or 13B) described herein. The first semiconductor layers 304 may include other materials, for example, a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GalnP, and/or GaInAsP, any other suitable material, or combinations thereof.

The semiconductor layers 304 and 306 may have different thicknesses. The first semiconductor layers 304 may have different thicknesses from one layer to another layer. The second semiconductor layers 306 may have different thicknesses from one layer to another layer. The first layer of the ML may be thicker than other semiconductor layers 304 and 306. Either the first semiconductor layer 304 or the second semiconductor layer 306 may be the topmost layer (or the layer farthest from the substrate 302). In an embodiment, the first semiconductor layer 304 may be the bottommost layer (or the layer most proximate to the substrate 302) of the ML.

The semiconductor layers 304 and 306 can be grown from the substrate 302. For example, each of the semiconductor layers 304 and 306 may be grown by a molecular beam epitaxy (MBE) process, a chemical vapor deposition (CVD) process such as a metal organic CVD (MOCVD) process, and/or other suitable growth processes. During the epitaxial growth, the crystal structure of the substrate 302 extends upwardly, resulting in the semiconductor layers 304 and 306 having the same crystal orientation with the substrate 302.

Referring to FIGS. 13 and 15, fin structures 400A, 400B, and 400C (collectively referred to as fin structures 400, fins 400, or active regions 400) are formed in the ML at the operation 204. The fin structures 400 each extend along the first lateral direction (e.g., the X axis) and spaced from one another along the second lateral direction (e.g., the Y axis) perpendicular to the first lateral direction. It is appreciated that the device 300 may include any suitable number of fin structures 400 while remaining within the scope of the present disclosure.

The fin structures 400 are formed by patterning the ML of semiconductor layers 304 and 306 and a top portion of the substrate 302 using, for example, photolithography and etching techniques. For example, a mask layer (which can include multiple layers such as, for example, a pad oxide layer and an overlying pad nitride layer; not depicted) is formed over a top surface of the ML. The pad oxide layer and the pad nitride layer may be formed using thermal oxidation, CVD, low-pressure chemical vapor deposition (LPCVD), or plasma enhanced chemical vapor deposition (PECVD), for example. The mask layer may then be patterned using photolithography techniques. Generally, photolithography techniques utilize a photoresist material (not shown) that is deposited, irradiated (exposed) through a photolithography mask, and developed to remove a portion of the photoresist material. The remaining photoresist material protects the underlying material, such as the mask layer in this example, from subsequent processing steps, such as etching. For example, the photoresist material is used to pattern the pad oxide layer and pad nitride layer to form a patterned mask. The photoresist material may be removed by a suitable method, such as plasma ashing or resist stripping, after patterning the mask layer.

The patterned mask is subsequently used to pattern exposed portions of the semiconductor layers 304 and 306 and the substrate 302 to form trenches (or openings) 410, thereby defining the fin structures 400 between adjacent trenches 410. The trenches 410 continuously extend along the first lateral direction. When multiple fin structures 400 are formed, such a trench 410 may be disposed between any adjacent ones of the fin structures. In some embodiments, the fin structures 400 are formed by etching trenches 410 in the semiconductor layers 304 and 306 and the substrate 302 using, for example, a dry etching process, e.g., a reactive ion etching (RIE) process, a neutral beam etching (NBE) process, other suitable process, or combinations thereof. The etching process may be anisotropic.

Referring to FIGS. 13 and 16, isolation structures 504 (alternatively referred to as isolation regions 504) are formed at the operation 206. The isolation structures 504 can be formed between adjacent ones of the fin structures 400, and partially embed or surround lower portions of the adjacent fin structures 400. In some embodiments, the isolation structures 504 are configured to electrically isolate neighboring active structures (e.g., adjacent fin structures or adjacent stacks of nanostructure channel layers) from one another. The isolation structures 504 may include an oxide, such as silicon oxide, a nitride, a low-k dielectric material (e.g., a dielectric material having a dielectric constant less than that of silicon oxide, which is about 3.9), such as phosphosilicate glass (PSG), borosilicate glass (BSG), boron-doped phosphosilicate glass (BPSG), undoped silicate glass (USG), other suitable materials, or combinations thereof.

The isolation structures 504 may be formed by first depositing an insulation material by any suitable process, such as high-density plasma chemical vapor deposition (HDP-CVD), flowable CVD (FCVD) (e.g., a CVD-based material deposition process in a remote plasma system and post curing to make it convert to another material, such as an oxide), other suitable processes, or combinations thereof. An anneal process may be performed once the insulation material is formed. A planarization process, such as a chemical mechanical polish (CMP) process or any other suitable process, may be performed remove any excess insulation material to expos a top surface of the fin structures 400 or the patterned mask, if present. The patterned mask may be removed by the planarization process, in some other embodiments. Subsequently, the insulation material is recessed to form the isolation structures 504, which are sometimes referred to as shallow trench isolations (STIs). The isolation structures 504 are recessed such that the fin structures 400 protrude from between neighboring isolation structures 504. The isolation structures 504 may be recessed to where a top surface of the isolation structures 504 is below the substrate 302. The isolation structures 504 may be recessed using a suitable etching process, such as one that is selective to the material of the isolation structures 504. For example, a dry etching process or a wet etching process using dilute hydrofluoric (dHF) acid may be performed to recess the isolation structures 504.

Referring to FIGS. 13 and 17, dummy gates structures 600A, 600B, and 600C (collectively referred to as dummy gate structures 600) are formed over the fin structures 400 at the operation 208. The dummy gate structures 600 each extend along the second lateral direction and spaced apart along the first lateral direction. In this regard, the dummy gate structure 600 are generally disposed perpendicular to the fin structures 400. In the present embodiments, the dummy gate structures 600 are placed where an active (e.g., metal) gate structure may later be formed. It is appreciated that the device 300 may include any suitable number of dummy gate structures 600 while remaining within the scope of the present disclosure.

In some embodiments, forming the dummy gate structures 600 includes depositing an etch-stop layer (not depicted) over a top surface of the fin structures 400, where the etch-stop layer is configured to protect the underlying fin structures 400 and may include silicon oxide or any other suitable material. Then, a dummy gate electrode layer 602 including polysilicon, for example, is deposited over the etch-stop layer as a blanket layer. In some embodiments, a hard mask 604 is deposited over the dummy gate electrode layer 602 and subsequently patterned using a photolithography process described herein. The dummy gate electrode layer 602 is then patterned using the patterned hard mask 604 as an etch mask, resulting in the dummy gate structures 600.

In some embodiments, though not depicted, the dummy gate structures 600 each further include a dummy gate dielectric layer (not shown) disposed between the etch-stop layer and the dummy gate electrode layer. The dummy gate dielectric layer may include, for example, silicon oxide, silicon nitride, silicon oxynitride, multilayers thereof, other suitable dielectric materials, or combinations thereof, and may be formed by thermal oxidation, chemical oxidation, CVD, ALD, other suitable methods, or combinations thereof.

Still referring to FIGS. 13 and 18, gate spacers 702 are formed on opposing sidewalls of each dummy gate structure 600. The gate spacers 702, which are alternatively referred to as top gate spacers 702, may include any suitable dielectric arranged in one or more spacer layers over the sidewalls of each dummy gate structure 600. In some embodiments, the gate spacers 702 are substantially similar to or the same as the gate spacers 17 described herein. The gate spacers 702 (or each spacer layer thereof) may be formed by first conformally depositing one or more dielectric materials over the dummy gate structures 600. Any suitable deposition method, such as thermal oxidation, chemical oxidation, CVD, ALD, other suitable methods, or combinations thereof, may be used to deposit the dielectric materials. Then, the dielectric material(s) may be etched using a suitable etching process, such as an anisotropic dry etching process, to form the gate spacers 702 along the opposing sidewalls of the dummy gate structures 600.

Referring to FIGS. 13 and 18, portions of each fin structure 400 are removed from the device 300 to form source/drain recesses 706 at the operation 210. Each source/drain recess 706 is interposed between two adjacent dummy gate structures 600 along the first lateral direction and thus provides the space for the subsequent formation of a corresponding source/drain feature. In various embodiments, the source/drain recesses 706 are formed by performing an etching process, such as an anisotropic etching process, to remove portions of the ML interposed between the dummy gate structures. The etching process may be selective to remove the materials of the ML and the substrate and may be implemented using the dummy gate structures as an etch mask, for example.

Subsequently, referring to FIGS. 13, 18, and 19, source/drain features 802 are formed in the source/drain recesses 708 over inner spacers 704, which are formed by replacing end portions of each of the first semiconductor layers 304 exposed in the source/drain recesses 706 at the operation 212. The inner spacers 704, which are alternatively referred to as bottom gate spacers 704, may include any suitable dielectric arranged in one or more spacer layers. In some embodiments, the inner spacers 704 are substantially similar to or the same as the inner spacers 11 described herein.

In some embodiments, referring to FIGS. 13 and 18, forming the inner spacers 704 includes performing an etching process (alternatively referred to as an etch-back process) to selectively remove the end portions of the first semiconductor layers 304 without removing, or substantially removing, the second semiconductor layers 306. In some embodiments, the etch-back process is implemented until a desired etch-back distance is achieved, resulting in the alignment of the etched first semiconductor layers 304 with the dummy gate structures 600 (i.e., the dummy gate electrode layer 602). Subsequently, the inner spacers 704 are formed on the etched end portions of the first semiconductor layers 304 in the source/drain recesses 706. The inner spacers 704 may be formed by depositing one or more layers of dielectric materials described herein by any suitable method, such as CVD, ALD, physical vapor deposition (PVD), other suitable methods, or combinations thereof. The dielectric material(s) may then be etched by a suitable etching process (e.g., an anisotropic dry etching process) to remove excess dielectric material(s) from the sidewalls of second semiconductor layers 306, the gate spacers 702, and the top surface of the substrate 302.

Subsequently, referring to FIGS. 13 and 19, source/drain features 802 are formed in the source/drain recesses 706 over the inner spacers 704. In some embodiments, the source/drain features 802 are substantially similar to or the same as the source/drain features 14A (or 14B) described herein. In some embodiments, sidewalls of the source/drain features 802 are aligned with the sidewalls of the inner spacers 704 and the second semiconductor layers 306 along the vertical direction. The source/drain features 802 may be formed using an epitaxial layer growth process on exposed ends of each of the second semiconductor layers 306 and the exposed substrate 302. For example, the growth process may include a selective epitaxial growth (SEG) process, CVD deposition techniques (e.g., vapor-phase epitaxy (VPE) and/or ultra-high vacuum CVD (UHV-CVD)), molecular beam epitaxy, other suitable epitaxial processes, or combinations thereof. In some embodiments, bottom surfaces of the source/drain features 802 are lower than a top surface of the isolation structures 504. In some embodiments, the dopants are introduced in-situ during the growth process. Alternatively, an implantation process may be performed to introduce the dopants after the growth process is implemented. After forming the source/drain features 802, an annealing process is performed to activate the dopants.

In some embodiments, as depicted in FIGS. 1B and 19, for example, a bottom portion of each source/drain recess is formed to below the top surface of the substrate 302 such that a bottommost portion of each of the source/drain features 802 is embedded in the substrate 302. In some embodiments, referring to FIG. 19, a bottom isolation layer 804 is formed at a bottom portion of each of the source/drain recesses 706 before forming the corresponding source/drain feature 802. In some embodiments, the bottom isolation layer 804 is substantially similar to or the same as the bottom isolation layer 15 described herein. The bottom isolation layer 804 may be formed by depositing a dielectric material in the source/drain recesses 706 by any suitable process, such as CVD, ALD, other processes, or combinations thereof. The dielectric material is subsequently etched back to expose a top portion of the source/drain recesses 706, leaving the bottom isolation layer 804 on the bottom portion of the source/drain recesses 706. The dielectric material may be etched by any suitable process, such as a dry etching, a wet etching, or combination thereof. The etching process may be controlled to ensure that a sufficient amount of the bottom isolation layer 804 remains in the source/drain recesses 706 before forming the source/drain features 802. In some embodiments, the bottom isolation layer 804 is configured to reduce or prevent current leakage between bottom portions of adjacent source/drain features 802. In some embodiments, the bottom isolation layer 804 is omitted from the device 300.

Referring to FIGS. 13 and 19, the dummy gate structures 600 are removed from the device 300 to form gate trenches (not depicted) at the operation 214. Replacing the dummy gate structures 600 includes first forming an ILD layer 806 over the source/drain features 802. In some embodiments, the ILD layer 806 are substantially similar to or the same as the ILD layer 19 described herein. The ILD layer 806 may be deposited by any suitable method, such as CVD, PECVD, FCVD, other suitable methods, or combinations thereof. Next, a planarization process, such as a CMP process, may be performed to achieve a level top surface for the ILD layer 806. The CMP may also remove the patterned hard mask 604. After performing the planarization process, the top surface of the ILD layer 806 may be substantially level or coplanar with a top surface of the dummy gate structures 600.

The dummy gate structures 600 may subsequently be removed by performing an etching process, such as a dry etching process, a wet etching process, other suitable processes, or combinations thereof. In various embodiments, the etching process is implemented using an etchant configured to remove the dummy gate electrode layer 602 that includes polysilicon, for example, without removing, or substantially removing, other components of the device 300, such as the gate spacers 702 and the topmost second semiconductor layer 306.

Subsequently, the first semiconductor layers 304 exposed by the gate trenches are selectively removed at the operation 216 to form openings (not depicted) each interposed between each pair of the inner spacers 704 along the first lateral direction and interposed between the second semiconductor layer 306 along the vertical direction. The first semiconductor layers 304 may be removed by a wet etching process or a dry etching process. In some embodiments, after performing the etching process, the second semiconductor layers 306, the inner spacers 704, and the gate spacers 702 (or at least a portion thereof) remain substantially intact. In this regard, top and bottom surfaces of the second semiconductor layers 306 are exposed in the openings.

Subsequently, still referring to FIGS. 13 and 19, active gate structures 900 are formed in the gate trenches and the openings at the operation 218. In the present embodiments, top portions of the active gate structures 900A, 900B, and 900C (collectively referred to as active gate structures 900) are formed in the gate trenches. In addition, bottom portions of the active gate structures 900 are formed in the openings below the corresponding top portions and between the inner spacers 704 such that each bottom portion wraps around the corresponding stack of second semiconductor layers 306. Stated differently, each bottom portion of the active gate structure 900 is interleaved with the second semiconductor layers 306. In some embodiments, the active gate structures 900 are substantially similar to or the same as the active gate structures 16 described herein.

The gate dielectric layer may be deposited by a conformal process, such as ALD, CVD, other suitable processes, or combinations thereof. Various layers of the gate metal may each be deposited by any suitable method such as ALD, CVD, PVD, electroless plating, electroplating, other suitable methods, or combinations thereof. Subsequently, the as-deposited gate dielectric layer and the gate metal are planarized using a suitable process, such as CMP, thereby exposing the top surfaces of the ILD layer 806.

Referring to FIGS. 13 and 20, gate isolation structures 920 and 922 are formed over the active gate structure 900 at the operation 220. Although two gate isolation structures 920 and 922 are depicted in FIG. 20, the device 300 may include any suitable number of the gate isolation structures similar to the gate isolation structure 920 or the gate isolation structure 922. It is further noted that in the top view depicted in FIG. 20, certain portions of the device 300, such as the ILD layer 806 and the gate spacers 702 are omitted for purposes of simplicity.

In some embodiments, the gate isolation structures 920 and 922 are substantially similar to or the same as the gate isolation structures 50 and 52 (or the gate isolation structures 60 and 64), respectively. For example, at least one of the gate isolation structures of the device 300, e.g., the gate isolation structure 920, includes a first portion 920A (alternatively referred to as a horizontal portion 920A) and a second portion 920B (alternatively referred to as a transverse portion 920B) extending from the first portion 920A along the second lateral direction. The first portion 920A generally extends along the first lateral direction and parallel to the fin 400. In the present embodiment, the first portion 920A is disposed between two adjacent fins 400, one of which is depicted in FIG. 20. The second portion 920B generally extends along the second lateral direction from the first portion 920A towards the fin 400, thereby intersecting one of the source/drain features 802. As such, the second portion 920B is generally perpendicular to the first portion 50A. In the depicted embodiment, the second portion 920B is disposed between two adjacent active gate structures 900. The gate isolation structure 922, as depicted in FIG. 20, only includes a first or horizontal portion 922A and does not include any second or transverse portion.

In some embodiments, the second portion 920B partially penetrates the source/drain feature 802 such that an end portion of the second portion 920B is surrounded by portions of the source/drain feature 802. In other words, similar to the embodiment of the second portion 50B of the gate isolation structure 50 depicted in FIGS. 1A-1C, the end portion of the second portion 920B replaces a portion of the source/drain feature 802. In this regard, a width W13 of the fin 400 along the second lateral direction is reduced by the penetration of the second portion 920B to a width W14, where the width W14 is greater than 0 but less than the width W13. Stated differently, the second portion 920B does not fully truncate or replace the source/drain feature 802 along the second lateral direction. In some embodiments, a section of the second portion 920B that penetrates the fin 400 may be defined by a length L_{cmg14}, the value of which determines an extent of reduction of a current through the resulting MOS device formed in the fin 400.

In some embodiments, forming the gate isolation structures 920 and 922 at the operation 220 includes patterning the device 300 to form first trenches (not depicted; corresponding to the first portions 920A and 922A) and at least a second trench (not depicted; corresponding to the second portion 920B) extending from one of the first trenches towards the fin 400. Each of the first trenches extends along the first lateral direction and over the active gate structures 900, thereby truncating or separating the active gate structures 900 into portions along the second lateral direction. The second trench extends along the second direction and interposed between two adjacent active gate structures 900 (e.g., the active gate structures 900B and 900C) along the first lateral direction. In some embodiments, the second trench is equidistant to each of the two active gate structures 900. In some embodiments, forming the first and the second trenches includes performing a series of photolithography and etching techniques described herein. Specifically, after forming a patterned mask layer (not depicted) over the device 300 and using the patterned mask layer as an etch mask, at least portions of the active gate structures 900, the gate spacers 702, and the ILD layer 806 are removed or etched (by a dry etching or a wet etching process, for example) to form the first trenches, and at least portions of the ILD layer 806 and one of the source/drain features 802 are removed to form the second trench. In the present embodiments, the source/drain feature 802 is only partially removed or etched such that a remaining portion of the source/drain feature 802 has the width W14 along the second lateral direction. In the present embodiments, the second trench is formed simultaneously or concurrently with the first trenches, i.e., patterned using the same photomask and the same etching process.

Subsequently, a dielectric layer is deposited over the device 300 to fill the first and the second trenches. The dielectric layer may include any suitable dielectric material, such as silicon oxide, silicon nitride, other suitable materials, or combinations thereof and may be deposited by any suitable process, such as CVD, FCVD, ALD, other processes, or combinations thereof. A planarization process, such as a CMP process, may then be performed to planarize a top surface of the resulting gate isolation structures 920 and 922 with a top surface of the active gate structures 900.

As described in detail herein, forming the gate isolation structures similar to the gate isolation structure 920 provides means for reducing the width of the fin 400 without requiring an additional fabrication step (e.g., an additional photolithography process), thereby reducing complexity and cost of the overall fabrication process. In addition, reducing the current of the MOS device in this manner provides area-saving benefits for improved device density at advanced technology nodes.

Thereafter, referring to FIGS. 13 and 20, additional operations may be performed at the operation 222. For example, referring to FIG. 20, for example, source/drain contacts 930A and 930B (collectively referred to as source/drain contacts 930) may be formed to electrically couple components of the device 300, such as the source/drain features 802, with interconnect features formed over the device 300. In some embodiments, the source/drain contacts 930 are substantially similar to or the same as the source/drain contacts 18 described herein. The source/drain contacts 930 may be formed by a series of patterning, etching, deposition, and planarization processes. In some embodiments, a top surface of each source/drain contact 930 are substantially planar with that of the active gate structure 900 and the gate isolation structures 920 (and 922). The interconnect features may be formed in respective dielectric layers (e.g., intermetal dielectric layers) formed over the device 300, where the interconnect features may include a plurality of vertical interconnect features (e.g., vias) and horizontal interconnect features (e.g., conductive lines). The interconnect features may include any suitable conductive materials, such as W, Cu, Co, Ru, Al, Ti, TIN, Ta, TaN, Au, Ag, Pt, other suitable materials, or combinations thereof. The dielectric layers may include any suitable materials similar to the component of the ILD layer 806.

FIG. 21 is a flowchart of a method 1400 of forming or manufacturing a semiconductor device, such as any of the devices 10A-10G, 300, and 1000, the memory device 100, the circuits 150, 160, and 170, and the modified circuits 150′, 160′, and 170′, in accordance with some embodiments. It is understood that additional operations may be performed before, during, and/or after the method 1400 depicted in FIG. 21.

In operation 1410 of the method 1400, a layout design of a semiconductor device is generated. The operation 1410 is performed by a processing device (e.g., processor 1502 of FIG. 22) configured to execute instructions for generating a layout design. In one approach, the layout design is generated by placing layout designs of one or more standard cells through a user interface. In one approach, the layout design is automatically generated by a processor executing a synthesis tool that converts a logic design (e.g., Verilog) into a corresponding layout design. In some embodiments, the layout design is rendered in a graphic database system (GDSII) file format. In some embodiments, the layout design includes one that is similar to any of the example layouts depicted in FIGS. 1A, 2A, 3A, 4A, 5A, 6A, 7A, 8B, 8C, 9B-9E, 10B, 10C, 11B, and 11C.

In operation 1420 of the method 1400, a semiconductor device is manufactured based on the layout design. In some embodiments, the operation 1420 of the method 1400 includes manufacturing at least one mask based on the layout design, and manufacturing a semiconductor device based on the at least one mask. Example manufacturing operations of the operation 1420 may include patterning, implantation, deposition, etching, planarization, the like, or combinations thereof, to form a plurality of front-end-of-line device features (e.g., the active regions 12A, 12B, OD1, OD3-OD8, and 400; the active gate structures 16, AG1-AG8, AG12-AG18, AG21-24, and 600; the source/drain features 14A, 14B, SD, PSD, NSD, and 802; the gate isolation structures 50, 52, 54, 60, 62, 64, and CMG1-CMG16; active region isolation structures DG1-DG4, and DG11-DG14; etc.), device-level contacts (e.g., the source/drain contacts 18 and MD1-MD7), and interconnect features including vias and conductive lines.

In some embodiments, the method 1400 is implemented as a standalone software application for execution by a processor. In some embodiments, the method 1400 is implemented as a software application that is a part of an additional software application. In some embodiments, the method 1400 is implemented as a plug-in to a software application. In some embodiments, the method 1400 is implemented as a software application that is a portion of an EDA tool. In some embodiments, the method 1400 is implemented as a software application that is used by an EDA tool. In some embodiments, the EDA tool is used to generate a layout design of the integrated circuit device. In some embodiments, the layout design is stored on a non-transitory computer readable medium. In some embodiments, the layout design is generated based on a netlist which is created based on the schematic design.

FIG. 22 is a schematic view of a system 1500 for designing and manufacturing an IC layout design, in accordance with some embodiments. The system 1500 generates or places one or more IC layout designs, as described herein. In some embodiments, the system 1500 manufactures one or more semiconductor devices based on the one or more IC layout designs, as described herein. The system 1500 includes a (e.g., hardware) processor 1502 and a non-transitory, computer readable storage medium 1504 encoded with, e.g., storing, computer program code 1506, e.g., a set of executable instructions. The computer readable storage medium 1504 is configured to interface with manufacturing machines for producing the semiconductor device. The processor 1502 is electrically coupled to the computer readable storage medium 1504 by a bus 1508. The processor 1502 is also electrically coupled to an I/O interface 1510 by the bus 1508. A network interface 1512 is also electrically connected to the processor 1502 by the bus 1508. Network interface 1512 is connected to a network 1514, so that the processor 1502 and the computer readable storage medium 1504 can connect to external elements via network 1514. The processor 1502 is configured to execute the computer program code 1506 encoded in the computer readable storage medium 1504 to cause the system 1500 to be usable for performing a portion or all of the operations as described in method 1400.

In some embodiments, the processor 1502 is a central processing unit (CPU), a multi-processor, a distributed processing system, an application specific integrated circuit (ASIC), and/or a suitable processing unit.

In some embodiments, the computer readable storage medium 1504 is an electronic, magnetic, optical, electromagnetic, infrared, and/or a semiconductor system (or apparatus or device). For example, the computer readable storage medium 1504 includes a semiconductor or solid-state memory, a magnetic tape, a removable computer diskette, a random-access memory (RAM), a read-only memory (ROM), a rigid magnetic disk, and/or an optical disk. In some embodiments using optical disks, the computer readable storage medium 1504 includes a compact disk-read only memory (CD-ROM), a compact disk-read/write (CD-R/W), and/or a digital video disc (DVD).

In some embodiments, the computer readable storage medium 1504 stores the computer program code 1506 configured to cause the system 1500 to perform the method 1400. In some embodiments, the computer readable storage medium 1504 also stores information needed for performing the method 1400 as well as information generated during the performance of the method 1400, such as layout design 1516, user interface 1518, fabrication unit 1520, and/or a set of executable instructions to perform the operation of method 1400.

In some embodiments, the computer readable storage medium 1504 stores instructions (e.g., the computer program code 1506) for interfacing with manufacturing machines. The instructions (e.g., the computer program code 1506) enable the processor 1502 to generate manufacturing instructions readable by the manufacturing machines to effectively implement the method 1400 during a manufacturing process.

The system 1500 includes the I/O interface 1510. The I/O interface 1510 is coupled to external circuitry. In some embodiments, the I/O interface 1510 includes a keyboard, keypad, mouse, trackball, trackpad, and/or cursor direction keys for communicating information and commands to the processor 1502.

The system 1500 also includes the network interface 1512 coupled to the processor 1502. The network interface 1512 allows the system 1500 to communicate with the network 1514, to which one or more other computer systems are connected. The network interface 1512 includes wireless network interfaces such as BLUETOOTH, WIFI, WIMAX, GPRS, or WCDMA; or wired network interface such as ETHERNET, USB, or IEEE-13154. In some embodiments, the method 1400 is implemented in two or more systems 1500, and information such as layout design, user interface and fabrication unit are exchanged between different systems 1500 by the network 1514.

The system 1500 is configured to receive information related to a layout design through the I/O interface 1510 or network interface 1512. The information is transferred to the processor 1502 by the bus 1508 to determine a layout design for producing an IC. The layout design is then stored in the computer readable storage medium 1504 as the layout design 1516. The system 1500 is configured to receive information related to a user interface through the I/O interface 1510 or network interface 1512. The information is stored in the computer readable storage medium 1504 as the user interface 1518. The system 1500 is configured to receive information related to a fabrication unit through the I/O interface 1510 or network interface 1512. The information is stored in the computer readable storage medium 1504 as the fabrication unit 1520. In some embodiments, the fabrication unit 1520 includes fabrication information utilized by the system 1500.

In some embodiments, the method 1400 is implemented by a manufacturing device to manufacture an integrated circuit using a set of masks manufactured based on one or more layout designs generated by the system 1500. In some embodiments, the system 1500 includes a manufacturing device (e.g., fabrication tool 1522) to manufacture an integrated circuit using a set of masks manufactured based on one or more layout designs of the present disclosure. In some embodiments, the system 1500 of FIG. 22 generates layout designs of an IC that are smaller than other approaches. In some embodiments, the system 1500 of FIG. 22 generates layout designs of a semiconductor device that occupy less area than other approaches.

FIG. 23 is a block diagram of an integrated circuit (IC)/semiconductor device manufacturing system 1600, and an IC manufacturing flow associated therewith, in accordance with at least one embodiment of the present disclosure.

In FIG. 23, the IC manufacturing system 1600 includes entities, such as a design house 1620, a mask house 1630, and an IC manufacturer/fabricator (“fab”) 1640, that interact with one another in the design, development, and manufacturing cycles and/or services related to manufacturing an IC device (semiconductor device) 1660 (e.g., the devices 10A-10G, 300, and 1000, the memory device 100, the circuits 150, 160, and 170, and the modified circuits 150′, 160′, and 170′). The entities in the IC manufacturing system 1600 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1620, mask house 1630, and IC fab 1640 is owned by a single company. In some embodiments, two or more of design house 1620, mask house 1630, and IC fab 1640 coexist in a common facility and use common resources.

The design house (or design team) 1620 generates an IC design layout 1622. The IC design layout 1622 includes various geometrical patterns designed for the IC device 1660. The geometrical patterns correspond to patterns of metal, oxide, or semiconductor layers that make up the various components of the IC device 1660 to be fabricated. The various layers combine to form various IC features. For example, a portion of the IC design layout 1622 includes various IC features, such as an active region, gate structures, source/drain regions, interconnect structures, and openings for bonding pads, to be formed in a semiconductor substrate (such as a silicon wafer) and various material layers disposed on the semiconductor substrate. The design house 1620 implements a proper design procedure to form the IC design layout 1622. The design procedure includes one or more of logic design, physical design or place and route. The IC design layout 1622 is presented in one or more data files having information of the geometrical patterns. For example, the IC design layout 1622 can be expressed in a GDSII file format or DFII file format.

The mask house 1630 includes mask data preparation 1632 and mask fabrication 1634. The mask house 1630 uses the IC design layout 1622 to manufacture one or more masks to be used for fabricating the various layers of the IC device 1660 according to the IC design layout 1622. The mask house 1630 performs the mask data preparation 1632, where the IC design layout 1622 is translated into a representative data file (“RDF”). The mask data preparation 1632 provides the RDF to the mask fabrication 1634. The mask fabrication 1634 includes a mask writer. A mask writer converts the RDF to an image on a substrate, such as a mask (reticle) or a semiconductor wafer. The design layout is manipulated by the mask data preparation 1632 to comply with particular characteristics of the mask writer and/or requirements of the IC fab 1640. In FIG. 23, the mask data preparation 1632 and mask fabrication 1634 are illustrated as separate elements. In some embodiments, the mask data preparation 1632 and mask fabrication 1634 can be collectively referred to as mask data preparation.

In some embodiments, the mask data preparation 1632 includes optical proximity correction (OPC) which uses lithography enhancement techniques to compensate for image errors, such as those that can arise from diffraction, interference, other process effects and the like. OPC adjusts the IC design layout 1622. In some embodiments, the mask data preparation 1632 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 1632 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during the mask fabrication 1634, which may undo part of the modifications performed by OPC in order to meet mask creation rules.

In some embodiments, the mask data preparation 1632 includes lithography process checking (LPC) that simulates processing that will be implemented by the IC fab 1640 to fabricate the IC device 1660. LPC simulates this processing based on the IC design layout 1622 to create a simulated manufactured device, such as the IC device 1660. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC can be repeated to further refine the IC design layout 1622.

It should be understood that the above description of the mask data preparation 1632 has been simplified for the purposes of clarity. In some embodiments, the mask data preparation 1632 includes additional features such as a logic operation (LOP) to modify the IC design layout according to manufacturing rules. Additionally, the processes applied to the IC design layout 1622 during the mask data preparation 1632 may be executed in a variety of different orders.

After the mask data preparation 1632 and during mask fabrication 1634, a mask or a group of masks are fabricated based on the modified IC design layout. In some embodiments, an electron-beam (e-beam) or a mechanism of multiple e-beams is used to form a pattern on a mask (photomask or reticle) based on the modified IC design layout. The mask can be formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask can be attenuated PSM or alternating PSM. The mask(s) generated by the mask fabrication 1634 is used in a variety of processes. For example, such a mask(s) is used in an ion implantation process to form various doped regions in the semiconductor wafer, in an etching process to form various etching regions in the semiconductor wafer, and/or in other suitable processes.

The IC fab 1640 is an IC fabrication entity that includes one or more manufacturing facilities for the fabrication of a variety of different IC products. In some embodiments, the IC fab 1640 is a semiconductor foundry. For example, there may be a first manufacturing facility for the front-end fabrication of a plurality of IC products (e.g., the active regions 12A, 12B, OD1, OD3-OD8, and 400; the active gate structures 16, AG1-AG8, AG12-AG18, AG21-24, and 600; the source/drain features 14A, 14B, SD, PSD, NSD, and 802; the gate isolation structures 50, 52, 54, 60, 62, 64, and CMG1-CMG16; active region isolation structures DG1-DG4, and DG11-DG14; etc.), while a second manufacturing facility may provide the middle end fabrication for the interconnection of the IC products (e.g., the source/drain contacts 18 and MD1-MD7, etc.) and a third manufacturing facility may provide the back end fabrication for the interconnection and packaging of the IC products, and a fourth manufacturing facility may provide other services for the foundry entity.

The IC fab 1640 uses the mask (or masks) fabricated by the mask house 1630 to fabricate the IC device 1660. Thus, the IC fab 1640 at least indirectly uses the IC design layout 1622 to fabricate the IC device 1660. In some embodiments, a semiconductor wafer 1642 is fabricated by the IC fab 1640 using the mask (or masks) to form the IC device 1660. The semiconductor wafer 1642 includes a silicon substrate or other proper substrate having material layers formed thereon. Semiconductor wafer further includes one or more of various doped regions, dielectric features, multilevel interconnects, and the like (formed at subsequent manufacturing steps).

The IC manufacturing system 1600 is shown as having the design house 1620, mask house 1630, and IC fab 1640 as separate components or entities. However, it should be understood that one or more of the design house 1620, mask house 1630, and IC fab 1640 are part of the same component or entity.

In one aspect of the present disclosure, a semiconductor structure is provided. The semiconductor structure includes a semiconductor fin protruding from a substrate and extending across the substrate along a first lateral direction. The semiconductor structure includes a plurality of gate structures disposed over the substrate, where each gate structure extends along a second lateral direction perpendicular to the first lateral direction. The semiconductor structure includes a gate isolation structure disposed over the gate structures. The gate isolation structure includes a first portion and a second portion connected to the first portion. The first portion extends over the gate structures along the first lateral direction. The second portion partially extends into the semiconductor fin along the second lateral direction.

In another aspect of the present disclosure, a semiconductor structure is provided. The semiconductor structure includes a semiconductor active region disposed over a substrate and extending across the substrate along a first lateral direction. The semiconductor active region including a first source/drain feature and a second source/drain feature. The semiconductor structure includes gate structures disposed over the substrate, where each gate structure extends along a second lateral direction perpendicular to the first lateral direction. The first and the second source/drain features are separated by one of the gate structures. The semiconductor structure includes a gate cut feature disposed over the substrate. The gate cut feature includes a first portion and a second portion extending from the first portion along the second lateral direction. The second portion replaces a portion of the first source/drain feature.

In yet another aspect of the present disclosure, a method of fabricating a semiconductor device is provided. The method includes forming a semiconductor fin protruding from a substrate and extending across the substrate along a first lateral direction. The method includes forming a plurality of gate structures over the substrate, where each gate structure extends along a second lateral direction perpendicular to the first lateral direction. The method includes forming a gate isolation structure over the substrate. The gate isolation structure includes a first portion and a second portion extending from the first portion, where the first portion cuts the gate structures and the second portion cuts the semiconductor fin.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a semiconductor fin protruding from a substrate and extending across the substrate along a first lateral direction;
a plurality of gate structures disposed over the substrate, each gate structure extending along a second lateral direction perpendicular to the first lateral direction; and
a gate isolation structure disposed over the gate structures, the gate isolation structure including a first portion and a second portion connected to the first portion, wherein the first portion extends over the gate structures along the first lateral direction, and wherein the second portion partially extends into the semiconductor fin along the second lateral direction.

2. The semiconductor structure of claim 1, wherein the second portion replaces a portion of the semiconductor fin.

3. The semiconductor structure of claim 1, wherein the second portion extends between two adjacent gate structures separated along the first lateral direction.

4. The semiconductor structure of claim 3, wherein the second portion is equidistant to each of the two adjacent gate structures.

5. The semiconductor structure of claim 1, wherein the semiconductor fin includes a source/drain feature interposed between two adjacent gate structures, and wherein the second portion replaces a portion of the source/drain feature.

6. The semiconductor structure of claim 5, further comprising a bottom isolation layer disposed on a bottom surface of the source/drain feature and a bottom surface of the second portion.

7. The semiconductor structure of claim 1, further comprising a source/drain contact extending between two adjacent gate structures and over a top surface of the second portion.

8. The semiconductor structure of claim 1, wherein the gate isolation structure further includes a third portion connected to the first portion, and wherein the third portion partially extends into the semiconductor fin parallel to the second portion.

9. A semiconductor structure, comprising:
a semiconductor active region disposed over a substrate and extending across the substrate along a first lateral direction, the semiconductor active region including a first source/drain feature and a second source/drain feature;
gate structures disposed over the substrate, each gate structure extending along a second lateral direction perpendicular to the first lateral direction, the first and the second source/drain features being separated by one of the gate structures; and
a gate cut feature disposed over the substrate, the gate cut feature including a first portion and a second portion extending from the first portion along the second lateral direction, wherein the second portion replaces a portion of the first source/drain feature.

10. The semiconductor structure of claim 9, wherein the gate cut feature further includes a third portion extending from the first portion along the second lateral direction, wherein the second portion replaces a portion of the second source/drain feature.

11. The semiconductor structure of claim 9, wherein:
the gate cut feature is a first gate cut feature extending over a first end of the gate structures,
the semiconductor structure further includes a second gate cut feature extending over a second end of the gate structures opposite to the first end, and
the second gate cut feature includes a third portion and a fourth portion extending from the third portion towards the first gate cut feature.

12. The semiconductor structure of claim 11, wherein the third portion replaces a portion of the first source/drain feature.

13. The semiconductor structure of claim 11, wherein the third portion replaces a portion of the second source/drain feature.

14. The semiconductor structure of claim 9, wherein:
the semiconductor active region has a width W1 along the second lateral direction,
the portion of the first source/drain feature replaced by the second portion has a length L1 along the second lateral direction, and
a different between the width W1 and the length L1 is greater than 0.

15. The semiconductor structure of claim 9, further comprising a bottom isolation layer below each of the first and the second source/drain features, wherein a bottom surface of the second portion abuts a top surface of the bottom isolation layer.

16. The semiconductor structure of claim 9, further comprising a source/drain contact extending along the second lateral direction and electrically coupled to one of the first and the second source/drain features, wherein the source/drain contact extends over and directly contacts a top surface of the second portion.

17. A method, comprising:
forming a semiconductor fin protruding from a substrate and extending across the substrate along a first lateral direction;
forming a plurality of gate structures over the substrate, each gate structure extending along a second lateral direction perpendicular to the first lateral direction; and
forming a gate isolation structure over the substrate, the gate isolation structure including a first portion and a second portion extending from the first portion, wherein the first portion cuts the gate structures, and wherein the second portion cuts the semiconductor fin.

18. The method of claim 17, wherein forming the gate isolation structure includes:
forming a first trench corresponding to the first portion and extending along the first lateral direction,
forming a second trench corresponding to the second portion and extending along the second lateral direction,
depositing a dielectric layer to fill the first trench and the second trench, and planarizing the dielectric layer to form the first and the second portions of the gate isolation structure.

19. The method of claim 18, wherein forming the first trench and forming the second trench are implemented simultaneously.

20. The method of claim 17, further comprising forming a source/drain contact extending along the second lateral direction and between two adjacent gate structures, wherein the source/drain contact extends over and directly contacts a top surface of the second portion.
